(19) United States
(12) Patent Application Publication
(10) Pub. No.: US 2019/0284443 A1
(43) Pub. Date: Sep. 19, 2019

(54) Composite Structure Including Glass-Like Layer and Methods of Forming

(71) Applicant: 3M INNOVATIVE PROPERTIES COMPANY, St. Paul, MN (US)

(72) Inventors: Audrey A. Sherman, Woodbury, MN (US); Claire Hartmann-Thompson, Lake Elmo, MN (US); Caleb T. Nelson, Woodbury, MN (US); John P. Baetzold, North St. Paul, MN (US); Trenton J. Wolter, St. Paul, MN (US); Martin B. Wolk, Woodbury, MN (US)

(21) Appl. No.: 15/761,684

(22) PCT Filed: Sep. 27, 2016
(86) PCT No.: PCT/US2016/053906

§ 371 Date: Mar. 20, 2018

Related U.S. Application Data
(60) Provisional application No. 62/235,481, filed on Sep. 30, 2015.

(51) Int. Cl. C09J 7/38; B32B 7/12; B32B 7/06; B32B 27/36; C09J 7/20; C09J 11/08

(52) U.S. Cl. CPC C09J 7/38; H01L 51/5253; B32B 7/06; B32B 27/36; C09J 7/20; C09J 11/08; B32B 2457/206; B32B 2405/00; B32B 2250/03; B32B 2250/24; C09J 2400/143; C09J 2205/114; C09J 2453/00; C09J 2205/102; C09J 2483/00; C09J 2203/326; C09J 2203/322; B32B 7/12

(57) ABSTRACT

Composite structures that include a first layer including a silicone block copolymer; a transition layer, the transition layer having a first surface contiguous with the first layer and a second opposing surface, the transition layer formed from the silicone block copolymer of the first layer; and a glass-like layer contiguous with the second surface of the transition layer, at least a portion of the glass-like layer formed from the transition layer.

### SUMMARY

Disclosed herein are composite structures that include a first layer including a silicone block copolymer; a transition layer, the transition layer having a first surface contiguous with the first layer and a second opposing surface, the transition layer formed from the silicone block copolymer of the first layer; and a glass-like layer contiguous with the second surface of the transition layer, at least a portion of the glass-like layer formed from the transition layer. Also disclosed herein are articles that include a primary structure and a composite structure disposed on some surface of the primary structure, the composite structure includes a first layer including a silicone block copolymer; a transition layer, the transition layer having a first surface contiguous with the first layer and a second opposing surface, the transition layer formed from the silicone block copolymer of the first layer; and a glass-like layer contiguous with the second surface of the transition layer, at least a portion of the glass-like layer formed from the transition layer.

Also disclosed are methods of forming a structure that includes a glass-like layer, the method including depositing a precursor first layer, the precursor first layer including a silicone block copolymer; and plasma treating the precursor first layer to convert at least some of the silicone block copolymer to the glass-like layer.

These and various other features and advantages will be apparent from a reading of the following detailed description.

### BRIEF DESCRIPTION OF THE DRAWINGS

The disclosure may be more completely understood in consideration of the following detailed description of various embodiments of the disclosure in connection with the accompanying drawings, in which:

FIG. 1 is a cross section of a portion of an illustrative composite structure.

FIG. 2 shows the atomic percentages of carbon (C), oxygen (O), and silicon (Si) measured using X-ray photoelectron spectroscopy (XPS) for sample E1 treated with O₂—SiMe₄ plasma from the Examples.

FIG. 3 shows the atomic percentages of carbon (C), oxygen (O), and silicon (Si) measured using X-ray photoelectron spectroscopy (XPS) for sample E1 treated with O₂ only plasma from the Examples.

FIG. 4 shows the atomic percentages of carbon (C), oxygen (O), and silicon (Si) measured using X-ray photoelectron spectroscopy (XPS) for sample E2 treated with O₂—SiMe₄ plasma from the Examples.

FIG. 5 shows the atomic percentages of carbon (C), oxygen (O), and silicon (Si) measured using X-ray photoelectron spectroscopy (XPS) for sample E2 treated with O₂ only plasma from the Examples.

FIG. 6 shows a scanning electron microscope (SEM) image of the edge seal formed in the Examples at 1500× magnification.

FIG. 7 shows a scanning electron microscope (SEM) image of the edge seal formed in the Examples at 15,000× magnification.

FIG. 8 shows an optical microscope image of the surface of the hex structured E3 layer (after the structured liner was removed).

FIG. 9 shows an optical microscope image of the surface of the linear structured E3 layer (after the structured liner was removed).

FIG. 10 shows an optical microscope image of the surface of the hex structured E3 layer after O₂—SiMe₄ plasma treatment.

FIG. 11 shows an optical microscope image of the surface of the linear structured E3 layer after O₂—SiMe₄ plasma treatment.

FIG. 12 shows a SEM image of the surface of the linear structured E3 layer before O₂—SiMe₄ plasma treatment.

FIG. 13 shows a SEM image of the surface of the linear structured E3 layer after O₂—SiMe₄ plasma treatment.

FIG. 14 shows a SEM image of the surface of the hex structured E3 layer (after the structured liner was removed).

FIG. 15 shows a SEM image of the surface of the hex structured E3 layer after O₂—SiMe₄ plasma treatment.

FIG. 16 shows a SEM image of the E2 sample plasma treated while stretched at 1500× magnification.

FIG. 17 shows a SEM image of the E2 sample plasma treated while stretched at 5000× magnification.

FIG. 18 shows a photographic image of E1 with no treatment after lines were drawn with a marker.

FIG. 19 shows a photographic image of E1 11 days after plasma treatment after lines were drawn with a marker.

FIG. 20 shows a photographic image of C2 11 days after plasma treatment after lines were drawn with a marker.

### DETAILED DESCRIPTION

In the following detailed description, reference is made to the accompanying drawings that form a part hereof, and in which are shown by way of illustration several specific embodiments. It is to be understood that other embodiments are contemplated and may be made without departing from the scope or spirit of the present disclosure. The following detailed description, therefore, is not to be taken in a limiting sense.

All scientific and technical terms used herein have meanings commonly used in the art unless otherwise specified. The definitions provided herein are to facilitate understanding of certain terms used frequently herein and are not meant to limit the scope of the present disclosure.

As used in this specification and the appended claims, the singular forms “a”, “an”, and “the” encompass embodiments having plural referents, unless the content clearly dictates otherwise.

As used in this specification and the appended claims, the term “or” is generally employed in its sense including “and/or” unless the content clearly dictates otherwise. The term “and/or” means one or all of the listed elements or a combination of any two or more of the listed elements.

As used herein, “have”, “having”, “include”, “including”, “comprise”, “comprising” or the like are used in their open ended sense, and generally mean “including, but not limited to”. It will be understood that “consisting essentially of”, “consisting of”, and the like are subsumed in “comprising” and the like. As used herein, “consisting essentially of,” as it relates to a composition, product, method or the like, means that the components of the composition, product, method or the like are limited to the enumerated components and any other components that do not materially affect the basic and novel characteristic(s) of the composition, product, method or the like.

The words “preferred” and “preferably” refer to embodiments of the invention that may afford certain benefits, under certain circumstances. However, other embodiments may also be preferred, under the same or other circumstances. Furthermore, the recitation of one or more preferred embodiments does not imply that other embodiments are not useful, and is not intended to exclude other embodiments from the scope of the disclosure, including the claims.

Also herein, the recitations of numerical ranges by endpoints include all numbers subsumed within that range (e.g., 1 to 5 includes 1, 1.5, 2, 2.75, 3, 3.80, 4, 5, etc. or 10 or less includes 10, 9.4, 7.6, 5, 4.3, 2.9, 1.62, 0.3, etc.). Where a range of values is “up to” a particular value, that value is included within the range.

Any direction referred to herein, such as “top,” “bottom,” “left,” “right,” “upper,” “lower,” and other directions and orientations are described herein for clarity in reference to the figures and are not to be limiting of an actual device or system or use of the device or system. Devices or systems as described herein may be used in a number of directions and orientations.

The term “contiguous” as used herein explains a relationship of two objects, for example two surfaces or layers, that share a common border or are touching. The term “adjacent” as used herein explains a relationship of two objects, for example two surfaces or layers that are near to each other but not necessarily touching. Adjacent includes contiguous.

The term “adhesive” as used herein refers to polymeric compositions useful to adhere together two adherends. An example of an adhesive is a pressure sensitive adhesive.

Pressure sensitive adhesive compositions are well known to those of ordinary skill in the art to possess properties including the following: (1) aggressive and permanent tack, (2) adherence with no more than finger pressure, (3) sufficient ability to hold onto an adherend, and (4) sufficient cohesive strength to be cleanly removable from the adherend. Materials that have been found to function well as pressure sensitive adhesives are polymers designed and formulated to exhibit the requisite viscoelastic properties resulting in a desired balance of tack, peel adhesion, and shear holding power. Obtaining the proper balance of properties is not a simple process.

The term “silicone-based” as used herein refers to macromolecules that contain silicone units. The terms silicone or siloxane are used interchangeably and refer to units with dialkyl or diaryl siloxane (—SiR₂O—) repeating units.

The term “urea-based” as used herein refers to macromolecules that are segmented copolymers which contain at least one urea linkage.

The term “amide-based” as used herein refers to macromolecules that are segmented copolymers which contain at least one amide linkage.

The term “urethane-based” as used herein refers to macromolecules that are segmented copolymers which contain at least one urethane linkage.

The term “alkenyl” refers to a monovalent group that is a radical of an alkene, which is a hydrocarbon with at least one carbon-carbon double bond. The alkenyl can be linear, branched, cyclic, or combinations thereof and typically contains 2 to 20 carbon atoms. In some embodiments, the alkenyl contains 2 to 18, 2 to 12, 2 to 10, 4 to 10, 4 to 8, 2 to 8, 2 to 6, or 2 to 4 carbon atoms. Exemplary alkenyl groups include ethenyl, n-propenyl, and n-butenyl.

The term “alkyl” refers to a monovalent group that is a radical of an alkane, which is a saturated hydrocarbon. The alkyl can be linear, branched, cyclic, or combinations thereof and typically has 1 to 20 carbon atoms. In some embodiments, the alkyl group contains 1 to 18, 1 to 12, 1 to 10, 1 to 8, 1 to 6, or 1 to 4 carbon atoms. Examples of alkyl groups include, but are not limited to, methyl, ethyl, n-propyl, isopropyl, n-butyl, isobutyl, tert-butyl, n-pentyl, n-hexyl, cyclohexyl, n-heptyl, n-octyl, and ethylhexyl.

The term “halo” refers to fluoro, chloro, bromo, or iodo.

The term “haloalkyl” refers to an alkyl having at least one hydrogen atom replaced with a halo. Some haloalkyl groups are fluoroalkyl groups, chloroalkyl groups, and bromoalkyl groups. The term “perfluoroalkyl” refers to an alkyl group in which all hydrogen atoms are replaced by fluorine atoms.

The term “aryl” refers to a monovalent group that is aromatic and carbocyclic. The aryl can have one to five rings that are connected to or fused to the aromatic ring. The other ring structures can be aromatic, non-aromatic, or combinations thereof. Examples of aryl groups include, but are not limited to, phenyl, biphenyl, terphenyl, anthryl, naphthyl, acenaphthyl, anthraquinonyl, phenanthryl, anthracenyl, pyrenyl, perylenyl, and fluorenyl.

The term “alkylene” refers to a divalent group that is a radical of an alkane. The alkylene can be straight-chained, branched, cyclic, or combinations thereof. The alkylene often has 1 to 20 carbon atoms. In some embodiments, the alkylene contains 1 to 18, 1 to 12, 1 to 10, 1 to 8, 1 to 6, or 1 to 4 carbon atoms. The radical centers of the alkylene can be on the same carbon atom (i.e., an alkylidene) or on different carbon atoms.

The term “heteroalkylene” refers to a divalent group that includes at least two alkylene groups connected by a thio, oxy, or —NR— where R is alkyl. The heteroalkylene can be linear, branched, cyclic, substituted with alkyl groups, or combinations thereof. Some heteroalkylenes are poloxyyalkylenes where the heteroatom is oxygen such as for example,

—CH₂CH₂(OCH₂CH₂)ₙOCH₂CH₂—.

The term “arylene” refers to a divalent group that is carbocyclic and aromatic. The group has one to five rings that are connected, fused, or combinations thereof. The other rings can be aromatic, non-aromatic, or combinations thereof. In some embodiments, the arylene group has up to 5 rings, up to 4 rings, up to 3 rings, up to 2 rings, or one aromatic ring. For example, the arylene group can be phenylene.

The term “heteroarylene” refers to a divalent group that is carbocyclic and aromatic and contains heteroatoms such as sulfur, oxygen, nitrogen or halogens such as fluorine, chlorine, bromine or iodine.

The term “aralkylene” refers to a divalent group of formula -Ra-Ara- where Ra is an alkylene and Ara is an arylene (i.e., an alkylene is bonded to an arylene).

The term “alkoxy” refers to a monovalent group of formula —OR where R is an alkyl group.

Disclosed herein are composite structures that include a first layer including silicone block copolymer, a glass-like layer, and a transition layer positioned between the two. Also disclosed are methods of forming a structure, the method including depositing a first layer including silicone block copolymer and plasma treating the first layer to form a glass-like layer and a transition layer therebetween. Disclosed herein is the surprising discovery that plasma treatment of the surface of a silicone block copolymer layer, which is a hydrophobic surface, can convert that surface into a stable glass-like surface, which is a hydrophilic surface. The glass-like surface remains stable over time without any additional treatment or special handling. The glass-like surface can have additional layers formed thereon, can be formed on various surfaces, can be laminated to itself after formation (to form multilayer constructions thereof), or any combination thereof. Composite structures formed and disclosed herein can be useful in numerous applications, including graphics and display applications.

A cross section of an illustrative composite is depicted in FIG. 1. The composite structure 100 includes a first layer 110, a transition layer 120 and a glass-like layer 130. As seen in FIG. 1, the transition layer 120 is positioned between the first layer 110 and the glass-like layer 130.

The first layer, illustrated by first layer 110 in FIG. 1 can generally include silicone block copolymer. Silicone block copolymer, as used herein can refer to one or more than one type of silicone block copolymer. The first layer can include one or more than one silicone block copolymer and may alternatively include other components as well. In some illustrative embodiments, the silicone block copolymer can be a condensation silicone block copolymer. Illustrative specific examples of types of silicone block copolymers can include silicone polyurea copolymers, silicone polyoxamide copolymers, silicone polyurea-urethane block copolymers, silicone carbonate copolymers, or combinations thereof. In some illustrative embodiments, the silicone block copolymers can be part of an adhesive composition or in some embodiments part of a pressure sensitive adhesive composition.

One example of a useful class of silicone block copolymers are urea-based silicone polymers such as silicone polyurea block copolymers. Silicone polyurea block copolymers include the reaction product of a polydiorganosiloxane diamine (also referred to as a silicone diamine), a diisocyanate, and optionally an organic polyamine. Suitable silicone polyurea block copolymers are represented by the repeating unit (I):

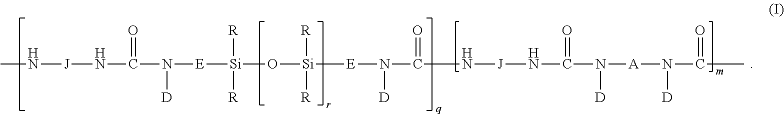

In formula I, each R is a moiety that, independently, is an alkyl moiety, having about 1 to 12 carbon atoms, and may be substituted with, for example, trifluoroalkyl or vinyl groups, a vinyl radical or higher alkenyl radical represented by the formula R²(CH₂)ₐCH═CH₂ wherein R² is —(CH₂)_{b}— or —(CH₂)_{c}CH═CH— and a is 1, 2 or 3; b is 0, 3 or 6; and c is 3, 4 or 5, a cycloalkyl moiety having from about 6 to 12 carbon atoms and may be substituted with alkyl, fluoroalkyl, and vinyl groups, or an aryl moiety having from about 6 to 20 carbon atoms and may be substituted with, for example, alkyl, cycloalkyl, fluoroalkyl and vinyl groups or R is a perfluoroalkyl group as described in U.S. Pat. No. 5,028,679, or a fluorine-containing group, as described in U.S. Pat. No. 5,236,997, or a perfluoroether-containing group, as described in U.S. Pat. Nos. 4,900,474 and 5,118,775, the disclosures of all of which are incorporated herein by reference thereto; typically, at least 50% of the R moieties are methyl radicals with the balance being monovalent alkyl or substituted alkyl radicals having from 1 to 12 carbon atoms, alkenyl radicals, phenyl radicals, or substituted phenyl radicals.

Each J is a polyvalent radical that is an arylene radical or an aralkylene radical having from about 6 to 20 carbon atoms, an alkylene or cycloalkylene radical having from about 6 to 20 carbon atoms, in some embodiments J is 2,6-tolylene, 4,4′-methylenediphenylene, 3,3′-dimethoxy-4,4′-biphenylene, tetramethyl-m-xylylene, 4,4′-methylenedicyclohexylene, 3,5,5-trimethyl-3-methylenecyclohexylene, 1,6-hexamethylene, 1,4-cyclohexylene, 2,2,4-trimethylhexylene and mixtures thereof.

Each E is a polyvalent radical that independently is an alkylene radical of 1 to 10 carbon atoms, an aralkylene radical or an arylene radical having 6 to 20 carbon atoms.

Each D is selected from the group consisting of hydrogen, an alkyl radical of 1 to 10 carbon atoms, phenyl, and a radical that completes a ring structure including A or E to form a heterocycle.

Each A is a polyvalent radical selected from the group consisting of alkylene, aralkylene, cycloalkylene, phenylene, heteroalkylene, including for example, polyethylene oxide, polypropylene oxide, polytetramethylene oxide, and copolymers and mixtures thereof.

m is a number that is 0 to about 1000. q is a number that is at least 1. r is a number that is at least 10, in some embodiments 15 to about 2000, or even 30 to 1500.

Useful silicone polyurea block copolymers are disclosed in, e.g., U.S. Pat. Pub. No. 20110020640; U.S. Pat. Nos. 5,512,650, 5,214,119, 5,461,134, and 7,153,924; and PCT Pub. Nos. WO 96/35458, WO 98/17726, WO 96/34028, WO 96/34030 and WO 97/40103, the disclosures of all of which are incorporated herein by reference thereto.

Examples of useful silicone diamines which can be used in the preparation of silicone polyurea block copolymers include polydiorganosiloxane diamines represented by formula II

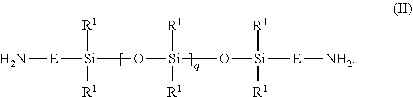

Each R¹ is independently an alkyl, haloalkyl, aralkyl, alkenyl, aryl, or aryl substituted with an alkyl, alkoxy, or halo, each E is independently an alkylene, aralkylene, or a combination thereof, and q is an integer of 0 to 1500.

The polydiorganosiloxane diamine of Formula II can be prepared by any known method and can have any suitable molecular weight, such as an average molecular weight in the range of 700 to 150,000 g/mole. Suitable polydiorganosiloxane diamines and methods of making the polydiorganosiloxane diamines are described, for example, in U.S. Pat. Nos. 3,890,269, 4,661,577, 5,026,890, 5,276,122, 5,214,119, 5,461,134, 5,512,650, 6,355,759, and 6,534,615 the disclosures of all of which are incorporated herein by reference thereto. Some polydiorganosiloxane diamines are commercially available, for example, from Shin Etsu Silicones of America, Inc., Torrance, Calif. and from Gelest Inc., Morrisville, Pa.

A polydiorganosiloxane diamine having a molecular weight greater than 2,000 g/mole or greater than 5,000 g/mole can be prepared using the methods described in U.S. Pat. Nos. 5,214,119, 5,461,134, and 5,512,650. One of the described methods involves combining under reaction conditions and under an inert atmosphere (a) an amine functional end blocker of formula IIa

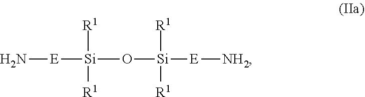

where E and R¹ are the same as defined for Formula II above; (b) sufficient cyclic siloxane to react with the amine functional end blocker to form a polydiorganosiloxane diamine having a molecular weight less than 2,000 g/mole; and (c) an anhydrous aminoalkyl silanolate catalyst of formula Iib

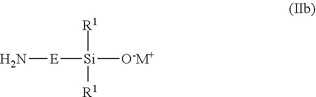

where E and R¹ are the same as defined in Formula II and M+ is a sodium ion, potassium ion, cesium ion, rubidium ion, or tetramethylammonium ion. The reaction is continued until substantially all of the amine functional end blocker is consumed and then additional cyclic siloxane is added to increase the molecular weight. The additional cyclic siloxane is often added slowly (e.g., drop wise). The reaction temperature is often conducted in the range of 80° C. to 90° C. with a reaction time of 5 to 7 hours. The resulting polydiorganosiloxane diamine can be of high purity (e.g., less than 2 weight percent, less than 1.5 weight percent, less than 1 weight percent, less than 0.5 weight percent, less than 0.1 weight percent, less than 0.05 weight percent, or less than 0.01 weight percent silanol impurities). Altering the ratio of the amine functional end blocker to the cyclic siloxane can be used to vary the molecular weight of the resulting polydiorganosiloxane diamine of Formula II.

Another method of preparing the polydiorganosiloxane diamine of Formula II includes combining under reaction conditions and under an inert atmosphere (a) an amine functional end blocker of formula IIc

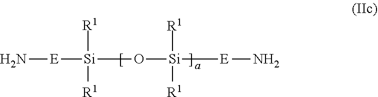

where R¹ and E are the same as described for Formula II and where the subscript a is equal to an integer of 1 to 150; (b) sufficient cyclic siloxane to obtain a polydiorganosiloxane diamine having an average molecular weight greater than the average molecular weight of the amine functional end blocker; and (c) a catalyst selected from cesium hydroxide, cesium silanolate, rubidium silanolate, cesium polysiloxanolate, rubidium polysiloxanolate, and mixtures thereof. The reaction is continued until substantially all of the amine functional end blocker is consumed. This method is further described in U.S. Pat. No. 6,355,759. This procedure can be used to prepare any molecular weight of the polydiorganosiloxane diamine.

Yet another method of preparing the polydiorganosiloxane diamine of Formula II is described in U.S. Pat. No. 6,531,620 the disclosures of which is incorporated herein by reference thereto. In this method, a cyclic silazane is reacted with a siloxane material having hydroxy end groups as shown in the following reaction.

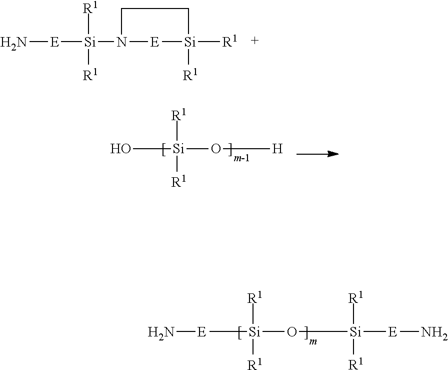

The groups R¹ and E are same as described for Formula II. The subscript m is an integer greater than 1.

Examples of polydiorganosiloxane diamines include, but are not limited to, polydimethylsiloxane diamine, polydiphenylsiloxane diamine, polytrifluoropropylmethylsiloxane diamine, polyphenylmethylsiloxane diamine, polydiethylsiloxane diamine, polydivinylsiloxane diamine, polyvinylmethylsiloxane diamine, poly(5-hexenyl)methylsiloxane diamine, and mixtures thereof.

The polydiorganosiloxane diamine component provides a means of adjusting the modulus of the resultant silicone polyurea block copolymer. In general, high molecular weight polydiorganosiloxane diamines provide copolymers of lower modulus whereas low molecular polydiorganosiloxane polyamines provide copolymers of higher modulus.

Examples of useful polyamines include polyoxyalkylene diamines including, e.g., polyoxyalkylene diamines commercially available under the trade designation D-230, D-400, D-2000, D-4000, ED-2001 and EDR-148 from Hunstman Corporation (Houston, Tex.), polyoxyalkylene triamines including, e.g., polyoxyalkylene triamines commercially available under the trade designations T-403, T-3000 and T-5000 from Hunstman, and polyalkylenes including, e.g., ethylene diamine and polyalkylenes available under the trade designations DYTEK A and DYTEK EP from DuPont (Wilmington, Del.).

The optional polyamine provides a means of modifying the modulus of the copolymer. The concentration, type and molecular weight of the organic polyamine influence the modulus of the silicone polyurea block copolymer.

The silicone polyurea block copolymer may include polyamine in an amount of no greater than about 3 moles, in some embodiments from about 0.25 to about 2 moles. Typically the polyamine has a molecular weight of no greater than about 300 g/mole.

Any polyisocyanate including, e.g., diisocyanates and triisocyanates, capable of reacting with the above-described polyamines can be used in the preparation of the silicone polyurea block copolymer. Examples of suitable diisocyanates include aromatic diisocyanates, such as 2,6-toluene diisocyanate, 2,5-toluene diisocyanate, 2,4-toluene diisocyanate, m-phenylene diisocyanate, p-phenylene diisocyanate, methylene bis(o-chlorophenyl diisocyanate), methylenediphenylene-4,4′-diisocyanate, polycarbodiimide-modified methylenediphenylene diisocyanate, (4,4′-diisocyanato-3,3′,5,5′-tetraethyl) diphenylmethane, 4,4-diisocyanato-3,3′-dimethoxybiphenyl (o-dianisidine diisocyanate), 5-chloro-2,4-toluene diisocyanate, and 1-chloromethyl-2,4-diisocyanato benzene, aromatic-aliphatic diisocyanates, such as m-xylylene diisocyanate and tetramethyl-m-xylylene diisocyanate, aliphatic diisocyanates such as 1,4-diisocyanatobutane, 1,6-diisocyanatohexane, 1,12-diisocyanatododecane and 2-methyl-1,5-diisocyanatopentane, and cycloaliphatic diisocyanates such as methylenedicyclohexylene-4,4′-diisocyanate, 3-isocyanatomethyl-3,5,5-trimethylcyclohexyl isocyanate (isophorone diisocyanate) and cyclohexylene-1,4-diisocyanate.

Any triisocyanate that can react with a polyamine, and in particular with the polydiorganosiloxane diamine is suitable. Examples of such triisocyanates include, e.g., polyfunctional isocyanates, such as those produced from biurets, isocyanurates, and adducts. Examples of commercially available polyisocyanates include portions of the series of polyisocyanates available under the trade designations DESMODUR and MONDUR from Bayer and PAPI from Dow Plastics.

The polyisocyanate is typically present in a stoichiometric amount based on the amount of polydiorganosiloxane diamine and optional polyamine.

In some embodiments, the first layer can include silicone block copolymers that are oxamide-based polymers such as polydiorganosiloxane polyoxamide block copolymers. Examples of polydiorganosiloxane polyoxamide block copolymers are presented, for example, in U.S. Pat. Pub. Nos. 20110020640 and 20070148475, the disclosures of all of which are incorporated herein by reference thereto. The polydiorganosiloxane polyoxamide block copolymer contains at least two repeat units of Formula III

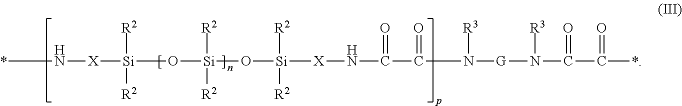

In formula III, each R² is independently an alkyl, haloalkyl, aralkyl, alkenyl, aryl, or aryl substituted with an alkyl, alkoxy, or halo, wherein at least 50 percent of the R² groups are methyl. Each X is independently an alkylene, aralkylene, or a combination thereof. Subscript n is independently an integer of 40 to 1500 and the subscript p is an integer of 1 to 10. Group G is a divalent group that is the residue unit that is equal to a diamine of formula R³HN-G-NHR³ minus the two —NHR³ groups. Group R³ is hydrogen or alkyl (e.g., an alkyl having 1 to 10, 1 to 6, or 1 to 4 carbon atoms) or R³ taken together with G and with the nitrogen to which they are both attached forms a heterocyclic group (e.g., R³HN-G-NHR³ is piperazine or the like). Each asterisk (*) indicates a site of attachment of the repeat unit to another group in the copolymer such as, for example, another repeat unit of Formula III.

Suitable alkyl groups for R² in Formula III typically have 1 to 10, 1 to 6, or 1 to 4 carbon atoms. Illustrative alkyl groups include, but are not limited to, methyl, ethyl, isopropyl, n-propyl, n-butyl, and iso-butyl. Suitable haloalkyl groups for R² often have only a portion of the hydrogen atoms of the corresponding alkyl group replaced with a halogen. Exemplary haloalkyl groups include chloroalkyl and fluoroalkyl groups with 1 to 3 halo atoms and 3 to 10 carbon atoms. Suitable alkenyl groups for R² often have 2 to 10 carbon atoms. Exemplary alkenyl groups often have 2 to 8, 2 to 6, or 2 to 4 carbon atoms such as ethenyl, n-propenyl, and n-butenyl. Suitable aryl groups for R² often have 6 to 12 carbon atoms. Phenyl is an exemplary aryl group. The aryl group can be unsubstituted or substituted with an alkyl (e.g., an alkyl having 1 to 10 carbon atoms, 1 to 6 carbon atoms, or 1 to 4 carbon atoms), an alkoxy (e.g., an alkoxy having 1 to 10 carbon atoms, 1 to 6 carbon atoms, or 1 to 4 carbon atoms), or halo (e.g., chloro, bromo, or fluoro). Suitable aralkyl groups for R² usually have an alkylene group having 1 to 10 carbon atoms and an aryl group having 6 to 12 carbon atoms. In some exemplary aralkyl groups, the aryl group is phenyl and the alkylene group has 1 to 10 carbon atoms, 1 to 6 carbon atoms, or 1 to 4 carbon atoms (i.e., the structure of the aralkyl is alkylene-phenyl where an alkylene is bonded to a phenyl group).

At least 50 percent of the R² groups are methyl. For example, at least 60 percent, at least 70 percent, at least 80 percent, at least 90 percent, at least 95 percent, at least 98 percent, or at least 99 percent of the R² groups can be methyl. The remaining R² groups can be selected from an alkyl having at least two carbon atoms, haloalkyl, aralkyl, alkenyl, aryl, or aryl substituted with an alkyl, alkoxy, or halo.

Each X in Formula III is independently an alkylene, aralkylene, or a combination thereof. Suitable alkylene groups typically have up to 10 carbon atoms, up to 8 carbon atoms, up to 6 carbon atoms, or up to 4 carbon atoms. Illustrative alkylene groups include methylene, ethylene, propylene, butylene, and the like. Suitable aralkylene groups usually have an arylene group having 6 to 12 carbon atoms bonded to an alkylene group having 1 to 10 carbon atoms. In some exemplary aralkylene groups, the arylene portion is phenylene. That is, the divalent aralkylene group is phenylene-alkylene where the phenylene is bonded to an alkylene having 1 to 10, 1 to 8, 1 to 6, or 1 to 4 carbon atoms. As used herein with reference to group X, “a combination thereof” refers to a combination of two or more groups selected from an alkylene and aralkylene group. A combination can be, for example, a single aralkylene bonded to a single alkylene (e.g., alkylene-arylene-alkylene). In one exemplary alkylene-arylene-alkylene combination, the arylene is phenylene and each alkylene has 1 to 10, 1 to 6, or 1 to 4 carbon atoms.

Each subscript n in Formula III is independently an integer of 40 to 1500. For example, subscript n can be an integer up to 1000, up to 500, up to 400, up to 300, up to 200, up to 100, up to 80, or up to 60. The value of n is often at least 40, at least 45, at least 50, or at least 55. For example, subscript n can be in the range of 40 to 1000, 40 to 500, 50 to 500, 50 to 400, 50 to 300, 50 to 200, 50 to 100, 50 to 80, or 50 to 60.

The subscript p is an integer of 1 to 10. For example, the value of p is often an integer up to 9, up to 8, up to 7, up to 6, up to 5, up to 4, up to 3, or up to 2. The value of p can be in the range of 1 to 8, 1 to 6, or 1 to 4.

Group G in Formula III is a residual unit that is equal to a diamine compound of formula R³HN-G-NHR³ minus the two amino groups (i.e., —NHR³ groups). Group R³ is hydrogen or alkyl (e.g., an alkyl having 1 to 10, 1 to 6, or 1 to 4 carbon atoms) or R³ taken together with G and with the nitrogen to which they are both attached forms a heterocyclic group (e.g., R³HN-G-NHR³ is piperazine). The diamine can have primary or secondary amino groups. In most embodiments, R³ is hydrogen or an alkyl. In many embodiments, both of the amino groups of the diamine are primary amino groups (i.e., both R³ groups are hydrogen) and the diamine is of formula H₂N-G-NH₂.

In some embodiments, G is an alkylene, heteroalkylene, polydiorganosiloxane, arylene, aralkylene, or a combination thereof. Suitable alkylenes often have 2 to 10, 2 to 6, or 2 to 4 carbon atoms. Illustrative alkylene groups include ethylene, propylene, butylene, and the like. Suitable heteroalkylenes are often polyoxyalkylenes such as polyoxyethylene having at least 2 ethylene units, polyoxypropylene having at least 2 propylene units, or copolymers thereof. Suitable polydiorganosiloxanes include the polydiorganosiloxane diamines of Formula II, which are described above, minus the two amino groups. Exemplary polydiorganosiloxanes include, but are not limited to, polydimethylsiloxanes with alkylene E groups (see Formula II). Suitable aralkylene groups usually contain an arylene group having 6 to 12 carbon atoms bonded to an alkylene group having 1 to 10 carbon atoms. Some exemplary aralkylene groups are phenylene-alkylene where the phenylene is bonded to an alkylene having 1 to 10 carbon atoms, 1 to 8 carbon atoms, 1 to 6 carbon atoms, or 1 to 4 carbon atoms. As used herein with reference to group G, “a combination thereof” refers to a combination of two or more groups selected from an alkylene, heteroalkylene, polydiorganosiloxane, arylene, and aralkylene. A combination can be, for example, an aralkylene bonded to an alkylene (e.g., alkylene-arylene-alkylene). In one exemplary alkylene-arylene-alkylene combination, the arylene is phenylene and each alkylene has 1 to 10, 1 to 6, or 1 to 4 carbon atoms.

The polydiorganosiloxane polyoxamide tends to be free of groups having a formula —R^{a}—(CO)—NH— where R^{a} is an alkylene. All of the carbonylamino groups along the backbone of the copolymeric material are part of an oxalylamino group (i.e., the —(CO)—(CO)—NH— group). That is, any carbonyl group along the backbone of the copolymeric material is bonded to another carbonyl group and is part of an oxalyl group. More specifically, the polydiorganosiloxane polyoxamide has a plurality of aminoxalylamino groups.

The polydiorganosiloxane polyoxamide can be a linear, block copolymer and can be an elastomeric material. Unlike many of the known polydiorganosiloxane polyamides that are generally formulated as brittle solids or hard plastics, the polydiorganosiloxane polyoxamides can be formulated to include greater than 50 weight percent polydiorganosiloxane segments based on the weight of the copolymer. The weight percent of the diorganosiloxane in the polydiorganosiloxane polyoxamides can be increased by using higher molecular weight polydiorganosiloxanes segments to provide greater than 60 weight percent, greater than 70 weight percent, greater than 80 weight percent, greater than 90 weight percent, greater than 95 weight percent, or greater than 98 weight percent of the polydiorganosiloxane segments in the polydiorganosiloxane polyoxamides. Higher amounts of the polydiorganosiloxane can be used to prepare elastomeric materials with lower modulus while maintaining reasonable strength.

Some of the polydiorganosiloxane polyoxamides can be heated to a temperature up to 200° C., up to 225° C., up to 250° C., up to 275° C., or up to 300° C. without noticeable degradation of the material. For example, when heated in a thermogravimetric analyzer in the presence of air, the copolymers often have less than a 10 percent weight loss when scanned at a rate 50° C. per minute in the range of 20° C. to about 350° C. Additionally, the copolymers can often be heated at a temperature such as 250° C. for 1 hour in air without apparent degradation as determined by no detectable loss of mechanical strength upon cooling.

Additional silicone polyoxamide copolymers that can be utilized can include those in U.S. Pat. Nos. 7,705,101 and 7,705,103, the disclosures of which are incorporated herein by reference thereto. Such additional silicone polyoxamide copolymers can be described as branched silicone polyoxamide copolymers. The branched polydiorganosiloxane polyamide copolymers are the condensation reaction product of (a) one or more amine compounds including at least one polyamine, the one or more amine compounds having primary or secondary amino groups with (b) a precursor having at least one polydiorganosiloxane segment and at least two ester groups. As used herein, the term “branched” is used to refer to a polymer chain having branch points that connect three or more chain segments. Examples of branched polymers include long chains having occasional and usually short branches including the same repeat units as the main chain (nominally termed a branched polymer). The branched polydiorganosiloxane polyamide block copolymers can optionally form cross-linked networks.

In certain embodiments, the block copolymers are branched polydiorganosiloxane polyoxamide block copolymers. Such branched polydiorganosiloxane polyoxamide copolymers are the condensation reaction product of (a) one or more amine compounds including at least one polyamine, the one or more amine compounds having primary or secondary amino groups with (b) a precursor having at least one polydiorganosiloxane segment and at least two oxalylamino groups.

The branched copolymers can have many of the desirable features of polysiloxanes such as low glass transition temperatures, thermal and oxidative stability, resistance to ultraviolet radiation, low surface energy and hydrophobicity, and high permeability to many gases. Additionally, the branched copolymers can have improved mechanical strength and elastomeric properties compared to polysiloxanes and linear polydiorganosiloxane polyamide block copolymers. At least some of the branched copolymers are optically clear, have a low refractive index, or both.

### Polydiorganosiloxane Polyamide Block Copolymers

A branched, polydiorganosiloxane polyamide block copolymer is provided that contains at least two repeat units of Formula IV-a.

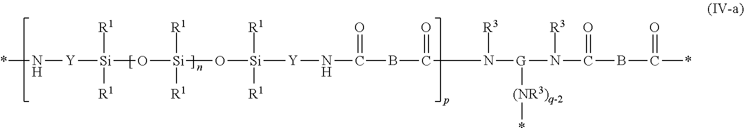

In formula IV-a, each R¹ is independently an alkyl, haloalkyl, aralkyl, alkenyl, aryl, or aryl substituted with an alkyl, alkoxy, or halo. Each Y is independently an alkylene, aralkylene, or a combination thereof. Subscript n is independently an integer of 0 to 1500 and the subscript p is an integer of 1 to 10. Group G is a polyvalent residue having a valence of q, wherein q is an integer greater than 2. In certain embodiments q can, for example, be equal to 3 or 4. Group R³ is hydrogen or alkyl (e.g., an alkyl having 1 to 10, 1 to 6, or 1 to 4 carbon atoms) or R3 taken together with G and with the nitrogen to which they are both attached forms a heterocyclic group (e.g., R³HN-G-NHR³ is piperazine or the like). Each B is independently a covalent bond, an alkylene of 4-20 carbons, an aralkylene, an arylene, or a combination thereof. When each group B is a covalent bond, the branched, polydiorganosiloxane polyamide block copolymer having repeat units of Formula IV-a is referred to as a branched, polydiorganosiloxane polyoxamide block copolymer, and preferably has repeat units of Formula IV-b shown below. Each asterisk (*) indicates a site of attachment of the repeat unit to another group in the copolymer such as, for example, another repeat unit of Formula IV (IV-a or IV-b). The branched copolymer can additionally include different repeat units such as, for example, repeat units of Formula IV, but wherein q is equal to 2.

In some embodiments, a branched, polydiorganosiloxane polyoxamide block copolymer contains at least two repeat units of Formula IV-b.

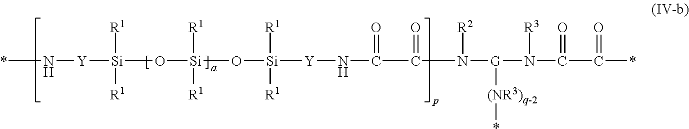

In IV-b formula, each R¹ is independently an alkyl, haloalkyl, aralkyl, alkenyl, aryl, or aryl substituted with an alkyl, alkoxy, or halo. Each Y is independently an alkylene, aralkylene, or a combination thereof. Subscript n is independently an integer of 0 to 1500 and the subscript p is an integer of 1 to 10. Group G is a polyvalent residue having a valence of q, wherein q is an integer greater than 2. In certain embodiments q can be, for example, equal to 3 or 4. Group R³ is hydrogen or alkyl (e.g., an alkyl having 1 to 10, 1 to 6, or 1 to 4 carbon atoms) or R³ taken together with G and with the nitrogen to which they are both attached forms a heterocyclic group (e.g., R³HN-G-NHR³ is piperazine or the like). Each asterisk (*) indicates a site of attachment of the repeat unit to another group in the copolymer such as, for example, another repeat unit of Formula IV (IV-a or IV-b).

Suitable alkyl groups for R¹ in Formula IV (IV-a or IV-b) typically have 1 to 10, 1 to 6, or 1 to 4 carbon atoms. Exemplary alkyl groups include, but are not limited to, methyl, ethyl, isopropyl, n-propyl, n-butyl, and iso-butyl. Suitable haloalkyl groups for IV often have only a portion of the hydrogen atoms of the corresponding alkyl group replaced with a halogen. Exemplary haloalkyl groups include chloroalkyl and fluoroalkyl groups with 1 to 3 halo atoms and 3 to 10 carbon atoms. Suitable alkenyl groups for IV often have 2 to 10 carbon atoms. Exemplary alkenyl groups often have 2 to 8, 2 to 6, or 2 to 4 carbon atoms such as ethenyl, n-propenyl, and n-butenyl. Suitable aryl groups for R1 often have 6 to 12 carbon atoms. Phenyl is an exemplary aryl group. The aryl group can be unsubstituted or substituted with an alkyl (e.g., an alkyl having 1 to 10 carbon atoms, 1 to 6 carbon atoms, or 1 to 4 carbon atoms), an alkoxy (e.g., an alkoxy having 1 to 10 carbon atoms, 1 to 6 carbon atoms, or 1 to 4 carbon atoms), or halo (e.g., chloro, bromo, or fluoro). Suitable aralkyl groups for IV usually have an alkylene group with 1 to 10 carbon atoms and an aryl group with 6 to 12 carbon atoms. In some exemplary aralkyl groups, the aryl group is phenyl and the alkylene group has 1 to 10 carbon atoms, 1 to 6 carbon atoms, or 1 to 4 carbon atoms (i.e., the structure of the aralkyl is alkylene-phenyl where an alkylene is bonded to a phenyl group).

In some repeat units of Formula IV (IV-a or IV-b), all R¹ groups can be one of alkyl, haloalkyl, aralkyl, alkenyl, aryl, or aryl substituted with an alkyl, alkoxy, or halo (e.g., all R′ Groups are an alkyl such as methyl or an aryl such as phenyl). In some compounds of Formula IV, the R¹ groups are mixtures of two or more selected from the group consisting of alkyl, haloalkyl, aralkyl, alkenyl, aryl, and aryl substituted with an alkyl, alkoxy, or halo in any ratio. Thus, for example, in certain compounds of Formula IV, 0%, 1%, 2, %, 5%, 10%, 20%, 30%, 40%, 50%, 60%, 70%, 80%, 90%, 95%, 98%, 99%, or 100% of the R¹ groups can be methyl; and 100%, 99%, 98%, 95%, 90%, 80%, 70%, 60%, 50%, 40%, 30%, 20%, 10%, 5%, 2%, 1%, or 0% of the R¹ groups can be phenyl.

In some repeat units of Formula IV (IV-a or IV-b), at least 50 percent of the R¹ groups are methyl. For example, at least 60 percent, at least 70 percent, at least 80 percent, at least 90 percent, at least 95 percent, at least 98 percent, or at least 99 percent of the R¹ groups can be methyl. The remaining R¹ groups can be selected from an alkyl having at least two carbon atoms, haloalkyl, aralkyl, alkenyl, aryl, or aryl substituted with an alkyl, alkoxy, or halo.

Each Y in Formula IV (IV-a or IV-b) is independently an alkylene, aralkylene, or a combination thereof. Suitable alkylene groups typically have up to 10 carbon atoms, up to 8 carbon atoms, up to 6 carbon atoms, or up to 4 carbon atoms. Exemplary alkylene groups include methylene, ethylene, propylene, butylene, and the like. Suitable aralkylene groups usually have an arylene group with 6 to 12 carbon atoms bonded to an alkylene group with 1 to 10 carbon atoms.

In some exemplary aralkylene groups, the arylene portion is phenylene. That is, the divalent aralkylene group is phenylene-alkylene where the phenylene is bonded to an alkylene having 1 to 10, 1 to 8, 1 to 6, or 1 to 4 carbon atoms. As used herein with reference to group Y, “a combination thereof” refers to a combination of two or more groups selected from an alkylene and aralkylene group. A combination can be, for example, a single aralkylene bonded to a single alkylene (e.g., alkylene-arylene-alkylene). In one exemplary alkylene-arylene-alkylene combination, the arylene is phenylene and each alkylene has 1 to 10, 1 to 6, or 1 to 4 carbon atoms.

Each subscript n in Formula IV (IV-a or IV-b) is independently an integer of 0 to 1500. For example, subscript n can be an integer up to 1000, up to 500, up to 400, up to 300, up to 200, up to 100, up to 80, up to 60, up to 40, up to 20, or up to 10. The value of n is often at least 1, at least 2, at least 3, at least 5, at least 10, at least 20, or at least 40. For example, subscript n can be in the range of 40 to 1500, 0 to 1000, 40 to 1000, 0 to 500, 1 to 500, 40 to 500, 1 to 400, 1 to 300, 1 to 200, 1 to 100, 1 to 80, 1 to 40, or to 20.

The subscript p is an integer of 1 to 10. For example, the value of p is often an integer up to 9, up to 8, up to 7, up to 6, up to 5, up to 4, up to 3, or up to 2. The value of p can be in the range of 1 to 8, 1 to 6, or 1 to 4.

Group G in Formula IV (IV-a or IV-b) is a residual unit that is equal to one or more amine compounds of the formula G(NHR³)_{q} minus the q amino groups (i.e., —NHR³ groups), where q is an integer greater than 2. As discussed hereinabove, the branched copolymer can additionally include different repeat units such as, for example, repeat units of Formula IV, but wherein q is equal to 2. The one or more amine compounds can have primary and/or secondary amino groups. Group R3 is hydrogen or alkyl (e.g., an alkyl having 1 to 10, 1 to 6, or 1 to 4 carbon atoms) or R3 taken together with G and with the nitrogen to which they are both attached forms a heterocyclic group (e.g., R³HN-G-NHR³ is piperazine). In most embodiments, R3 is hydrogen or an alkyl. In many embodiments, all of the amino groups of the one or more amine compounds are primary amino groups (i.e., all the R³ groups are hydrogen) and the one or more amine compounds are of the formula G(NH₂)_{q}.

In certain embodiments, the one or more amine compounds are a mixture of (i) a diamine compound of formula R³ HN-G-NHR³ and (ii) a polyamine compound of formula G(NHR3)q, where q is an integer greater than 2. In such embodiments, the polyamine compound of formula G(NHR³)_{q} can be, but is not limited to, triamine compounds (i.e., q=3), tetraamine compounds (i.e., q=4), and combinations thereof. In such embodiments, the number of equivalents of polyamine (ii) per equivalent of diamine (i) is preferably at least 0.001, more preferably at least 0.005, and most preferably at least 0.01. In such embodiments, the number of equivalents of polyamine (ii) per equivalent of diamine (i) is preferably at most 3, more preferably at most 2, and most preferably at most 1.

When G includes residual units that are equal to (i) a diamine compound of formula R3HN-G-NHR³ minus the two amino groups (i.e., —NHR³ groups), C can be an alkylene, heteroalkylene, polydiorganosiloxane, arylene, aralkylene, or a combination thereof. Suitable alkylenes often have 2 to 10, 2 to 6, or 2 to 4 carbon atoms. Exemplary alkylene groups include ethylene, propylene, butylene, and the like. Suitable heteroalkylenes are often polyoxyalkylenes such as polyoxyethylene having at least 2 ethylene units, polyoxypropylene having at least 2 propylene units, or copolymers thereof. Suitable polydiorganosiloxanes include the polydiorganosiloxane diamines of Formula III, which are described below, minus the two amino groups. Exemplary polydiorganosiloxanes include, but are not limited to, polydimethylsiloxanes with alkylene Y groups. Suitable aralkylene groups usually contain an arylene group having 6 to 12 carbon atoms bonded to an alkylene group having 1 to 10 carbon atoms. Some exemplary aralkylene groups are phenylene-alkylene where the phenylene is bonded to an alkylene having 1 to 10 carbon atoms, 1 to 8 carbon atoms, 1 to 6 carbon atoms, or 1 to 4 carbon atoms. As used herein with reference to group C, “a combination thereof” refers to a combination of two or more groups selected from an alkylene, heteroalkylene, polydiorganosiloxane, arylene, and aralkylene. A combination can be, for example, an aralkylene bonded to an alkylene (e.g., alkylene-arylene-alkylene). In one exemplary alkylene-arylene-alkylene combination, the arylene is phenylene and each alkylene has 1 to 10, 1 to 6, or 1 to 4 carbon atoms.

In preferred embodiments, the polydiorganosiloxane polyamide is a branched polydiorganosiloxane polyoxamide. The branched polydiorganosiloxane polyamide tends to be free of groups having a formula —R^{a}—(CO)—NH— where R^{a} is an alkylene. All of the carbonylamino groups along the backbone of the copolymeric material are part of an oxalylamino group (i.e., the —(CO)—(CO)—NH— group). That is, any carbonyl group along the backbone of the copolymeric material is bonded to another carbonyl group and is part of an oxalyl group. More specifically, the branched polydiorganosiloxane polyoxamide has a plurality of aminoxalylamino groups.

The polydiorganosiloxane polyamide is a branched, block copolymer and can be an elastomeric material. Unlike many of the known polydiorganosiloxane polyamides that are generally formulated as brittle solids or hard plastics, the polydiorganosiloxane polyamides can be formulated to include greater than 50 weight percent polydiorganosiloxane segments based on the weight of the copolymer. The weight percent of the diorganosiloxane in the polydiorganosiloxane polyamides can be increased by using higher molecular weight polydiorganosiloxanes segments to provide greater than 60 weight percent, greater than 70 weight percent, greater than 80 weight percent, greater than 90 weight percent, greater than 95 weight percent, or greater than 98 weight percent of the polydiorganosiloxane segments in the polydiorganosiloxane polyamides. Higher amounts of the polydiorganosiloxane can be used to prepare elastomeric materials with lower modulus while maintaining reasonable strength.

Such branched silicone polyoxyamide block copolymers (e.g, polydiorganosiloxane polyamide polymers) can be prepared as discussed in U.S. Pat. Nos. 7,705,101 and 7,705,103, for example.

The polydiorganosiloxane polyoxamide copolymers have many of the desirable features of polysiloxanes such as low glass transition temperatures, thermal and oxidative stability, resistance to ultraviolet radiation, low surface energy and hydrophobicity, and high permeability to many gases. Additionally, the copolymers exhibit good to excellent mechanical strength.

As discussed above, another useful class of silicone block copolymers includes urethane-based silicone polymers such as silicone polyurea-urethane block copolymers. Silicone polyurea-urethane block copolymers include the reaction product of a polydiorganosiloxane diamine (also referred to as silicone diamine), a diisocyanate, and an organic polyol. Such materials are structurally very similar to the structure of Formula I except that the —N(D)-A-N(D)-links are replaced by —O-A-O— links, as seen in Formula V below

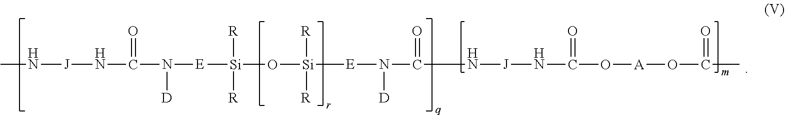

In formula V, J, D, E, R, A, r, q, and m are as defined above in Formula I. Specific, illustrative examples of silicone polyurea-urethane block copolymers can be found, for example, in U.S. Pat. No. 5,214,119, the disclosure of which is incorporated herein by reference thereto.

Illustrative silicone polyurea-urethane-based silicone polymers can be prepared in the same fashion as the urea-based silicone polymers of formula I, except that an organic polyol is substituted for the organic polyamine. Typically, since the reaction between an alcohol group and an isocyanate group is slower than the reaction between an amine group and an isocyanate group, a catalyst such as a tin catalyst commonly used in polyurethane chemistry, can be used.

As discussed above, another useful class of silicone block copolymers includes silicone carbonate block copolymers. Such copolymers include blocks of siloxane and blocks of polycarbonate. Further description of such silicone carbonate block copolymers can be found, for example in U.S. Pat. Pub. No. 20140357781, the disclosure of which is incorporated herein by reference thereto. An illustrative example of a silicone carbonate block copolymer is commercially available as SABIC™ LEXAN™ Resin EXL1414T (SABIC Innovative Plastics Holding IP BV).

Compositions that can be utilized to form a first layer can also include other optional components. In some embodiments, compositions can also include tackifying resins such as for example MQ tackifying resins. The MQ tackifying resin and the silicone polyoxamide copolymer generally are present in the form of a blend of MQ tackifying resin and silicone copolymer. Typically the silicone copolymer is present in the composition, which could be characterized as a silicone-based pressure sensitive adhesive composition, in an amount of from 30% by weight to 90% by weight, 30% by weight to 85% by weight, 30% by weight to 70% by weight, or even 45% by weight to 55% by weight. The MQ tackifying resin, if present, is typically present in an amount of at least 10% by weight. In some embodiments, the MQ tackifying resin is present in the composition in an amount not less than 15% by weight, not less than 30% by weight, not less than 40% by weight, or not less than 45% by weight. In some embodiments, the MQ tackifying resin is present in the composition in an amount not greater than 80% by weight, not greater than 70% by weight, not greater than 60% by weight, or not greater than 55% by weight.

Useful MQ tackifying resins include, e.g., MQ silicone resins, MQD silicone resins, and MQT silicone resins, which also may be referred to as copolymeric silicone resins and which typically have a number average molecular weight of about 100 to about 50,000, or about 500 to about 20,000 and generally have methyl substituents. The MQ silicone resins include both non-functional and functional resins, the functional resins having one or more functionalities including, for example, silicon-bonded hydrogen, silicon-bonded alkenyl, and silanol.

MQ silicone resins are copolymeric silicone resins having R′₃SiO_{1/2} units (M units) and SiO_{4/2} units (Q units). Such resins are described in, for example, Encyclopedia of Polymer Science and Engineering, vol. 15, John Wiley & Sons, New York, (1989), pp. 265 to 270, and U.S. Pat. Nos. 2,676,182; 3,627,851; 3,772,247; and 5,248,739, the disclosures of all of which are incorporated herein by reference thereto. MQ silicone resins having functional groups are described in U.S. Pat. No. 4,774,310, which describes silyl hydride groups, U.S. Pat. No. 5,262,558, which describes vinyl and trifluoropropyl groups, and U.S. Pat. No. 4,707,531, which describes silyl hydride and vinyl groups, the disclosures of all of which are incorporated herein by reference thereto. The above-described resins are generally prepared in solvent. Dried or solventless MQ silicone resins are prepared as described in U.S. Pat. Nos. 5,319,040; 5,302,685; and 4,935,484 the disclosures of all of which are incorporated herein by reference thereto.

MQD silicone resins are terpolymers having R′₃SiO_{1/2} units (M units), SiO_{4/2} units (Q units), and R′₂SiO_{2/2} units (D units) as described, e.g., in U.S. Pat. No. 5,110,890 and Japanese Kokai HEI 2-36234, the disclosures of all of which are incorporated herein by reference thereto.

MQT silicone resins are terpolymers having R₃SiO_{1/2} units (M units), SiO_{4/2} units (Q units), and RSiO_{3/2} units (T units) (MQT resins).

Commercially available MQ resins include SR545 silicone resin in toluene available from Momentive Performance Materials (Waterford, N.Y.), MQOH resins which are MQ silicone resins in toluene available from PCR, Inc. (Gainesville, Fla.). Such resins are generally supplied in organic solvent. These organic solutions of MQ silicone resin may be used as is or may be dried by any number of techniques known in the art including, e.g., spray drying, oven drying, and steam separation, to provide a MQ silicone resin at 100 percent non-volatile content. The MQ silicone resin can also include blends of two or more silicone resins.

Just as the silicone block copolymers may be made from a variety of processes, compositions including them, e.g., adhesive compositions such as pressure sensitive adhesive compositions, may also be prepared by a variety of processes. The compositions may be prepared in a solvent-based process, a solventless process or a combination thereof.

In solvent-based processes, the MQ silicone resin, if used, can be introduced before, during or after the reactants used to form the silicone block copolymer, such as polyamines and polyisocyanates, have been introduced into the reaction mixture. The reaction may be carried out in a solvent or a mixture of solvents. The solvents may be nonreactive with the reactants. The starting materials and final products may remain completely miscible in the solvents during and after the completion of the polymerization. These reactions can be conducted at room temperature or up to the boiling point of the reaction solvent. The reaction is generally carried out at ambient temperature up to 50° C. Additionally, the silicone block copolymer may be prepared in a solvent mixture with the MQ resin added later, after the copolymer has been formed.

In substantially solventless processes, the reactants used to form the silicone block copolymer and the MQ silicone resin, if used, are mixed in a reactor and the reactants are allowed to react to form the silicone block copolymer, and thus form an adhesive composition, e.g., a pressure sensitive adhesive composition. Additionally, the silicone block copolymer can be made in a solventless process, in for example a mixer or extruder, and either be isolated or simply transferred to an extruder and mixed with MQ silicone resin.

One useful method that includes a combination of a solvent-based process and a solventless process includes preparing the silicone block copolymer using a solventless process and then mixing the silicone block copolymer with the MQ resin solution in a solvent.

Compositions for forming the first layer can be solvent-free or can contain a solvent. Suitable solvents include, but are not limited to, toluene, tetrahydrofuran, dichloromethane, aliphatic hydrocarbons (e.g., alkanes such as hexane), or mixtures thereof. The compositions can further include other additives to provide desired properties. For example, dyes and pigments can be added as colorant; electrically and/or thermally conductive compounds can be added to make the adhesive electrically and/or thermally conductive or antistatic; antioxidants and antimicrobial agents can be added; and ultraviolet light stabilizers and absorbers, such as hindered amine light stabilizers (HALS), can be added to stabilize the adhesive against ultraviolet degradation and to block certain ultraviolet wavelengths from passing through the article. Other additives include, but are not limited to, adhesion promoters, fillers (e.g., fumed silica, carbon fibers, carbon black, glass beads, glass and ceramic bubbles, glass fibers, mineral fibers, clay particles, organic fibers such as nylon, metal particles, or unexpanded polymeric microspheres), tack enhancers, blowing agents, hydrocarbon plasticizers, and flame-retardants.

First layers, as described herein may be free standing or may be disposed on a substrate. The substrate may be a release liner, a rigid surface that may include other structures or layers, a tape backing, a film, a sheet, or any other surface of any other material, article or device.

The first layer can be prepared using a variety of common methods. For example, a composition can be coated onto a release liner, coated directly onto a substrate or a backing, or formed as a separate layer (e.g., coated onto a release liner) and then laminated to a substrate. In some embodiments a pressure sensitive adhesive composition can be deposited on a substrate that functions as a release liner and a second film is then disposed thereon, i.e. it is disposed between two release liners. A first layer, in such a construction, can then be applied to any article upon which a glass-like outer layer (or some construction including a glass-like outer layer) is desired. First layers can also be formed using other methods, including for example extruding the composition (e.g., including coextrusion) and blowing the composition into a layer (e.g., blown fibers).

The first layer can be described as having a carbon to oxygen ratio (“C:O”). The carbon to oxygen ratio can be calculated or approximated based on the known molecular structure of the material(s) making up the first layer, can be measured using atomic characterization methods of the first layer, or combinations thereof. In some embodiments, the carbon to oxygen ratio can be based on molar amounts, atomic amounts, or mass amounts. In some embodiments, the carbon to oxygen ratio can be calculated or approximated using amounts of moles, rendering the carbon to oxygen ratio a molar carbon to oxygen ratio. In some embodiments where the carbon to oxygen ratio is calculated, the ratio may be approximate because of the nature of the material(s) in the first layer. A first example of this includes first layers that include one or more silicone block copolymers that include polydimethylsiloxane (PDMS) units. PDMS units can have a relatively high polydispersity, which implies that they have a non-uniform structure, i.e., a non-uniform number of PDMS units in molecules. When calculating a carbon to oxygen ratio, the number of PDMS units must be assumed, the difference between the assumed number of units and the actual number of units will cause the calculated carbon to oxygen ratio to vary from the actual carbon to oxygen ratio. A second example of this includes first layers that include MQ tackifying resins. MQ tackifying resins typically have an imprecisely defined structure. However, in order to calculate a carbon to oxygen ratio, a structure of the MQ resin must be assumed. The difference in the assumed structure and the actual structure will cause the calculated carbon to oxygen ratio to vary from the actual carbon to oxygen ratio.

Methods of measuring carbon to oxygen ratios can include x-ray photoelectron spectroscopy (XPS) (also known as electron spectroscopy for chemical analysis (ESCA)). XPS, as well as other surface characterization methods provide measurements of the surface. Precision in measurements of carbon to oxygen ratios depends on the particular method being used for the measurement, different ways of analyzing data obtained, the particular instruments being utilized, and combinations thereof. Units measured to obtain a carbon to oxygen ratio can vary based on the particular measurement method being utilized. In some embodiments, amounts of moles can be utilized, percentage atomic concentrations, or any such units. In some embodiments where XPS is utilized to measure a carbon to oxygen ratio, percentage of atomic concentrations can be utilized.

XPS characterizes the surface of a material. Typically XPS provides, intensities of peaks which can be represented as percentages, the intensity of a given atom/the total intensity of atoms being measured*100. In some embodiments, carbon (C), oxygen (O), and silicon (Si) can be measured using XPS and carbon and oxygen (as well as silicon) percentages can be determined. These percentages can be utilized to determine carbon to oxygen ratios at a surface of a composite structure. The carbon to oxygen ratio of a layer (e.g., the first layer, the transition layer, or the glass-like layer) can be determined by characterizing the surface of the layer, removing that surface, characterizing the newly exposed surface, and repeating that process until the entire layer has been characterized. XPS can utilize sputtering techniques to expose new surfaces and can combine the characterization step and the exposing step in a continuous process to characterize many surfaces through the depth of a layer to obtain a depth profile. The carbon to oxygen ratio of numerous exposed surfaces within a layer can be utilized to determine the carbon oxygen ratio of the layer. This can be accomplished by averaging the carbon to oxygen ratio of numerous surfaces within the layer, or determining a range of carbon to oxygen ratios of the numerous surfaces within the layer for example. In some embodiments, the carbon to oxygen ratio of a layer (e.g., a first layer, a transition layer, or a glass-like layer for example) can be the arithmetic mean of numerous carbon to oxygen ratios determined by XPS (for example) for surfaces within the layer.

Carbon to oxygen ratios discussed herein are typically presented as normalized carbon to oxygen ratios, in that the oxygen amount has been normalized to 1 (i.e., the value for the amount of oxygen has been divided into both the number for the oxygen and the carbon).

In some embodiments, a first layer can have a calculated molar carbon to oxygen ratio (C:O) of from 2 to 4 moles C: 1 mole O. In some embodiments, a first layer can have a calculated molar carbon to oxygen ratio of from 2 to 3 moles C: 1 mole O. In some embodiments, a first layer can have a calculated molar carbon to oxygen ratio of from 2 to 2.5 moles C: 1 mole O.

In some embodiments, a first layer can have a measured molar carbon to oxygen ratio (C:O) of from 2 to 4 atomic percentage C: 1 atomic percentage O. In some embodiments, a first layer can have a measured carbon to oxygen ratio of from 2 to 3 atomic percentage C: 1 atomic percentage O. In some embodiments, a first layer can have a measured carbon to oxygen ratio of from 2 to 2.5 atomic percentage C: 1 atomic percentage O.

The first layer generally has less oxygen in it than both the transition layer and the glass-like layer. Stated another way, at least some of the carbon in the material of the first layer have been replaced with oxygen in both the transition layer and the glass-like layer. It can also be said that the first layer has more carbon in it than both the transition layer and the glass-like layer. As such, in a carbon to oxygen ratio where the oxygen amount has been normalized to 1 (i.e., the value for the amount of oxygen has been divided into both the number for the oxygen and the carbon), the value for the carbon will always be higher in the first layer than both the transition layer and the glass-like layer.

The first layer can also be described as having a particular hardness level or elasticity. In some embodiments, the elastic modulus, indentation hardness, or other measures of elasticity and/or hardness can be utilized to quantify or characterize the hardness of the first layer. The first layer is generally less harder than both the transition layer and the glass-like layer. Stated another way, the first layer is generally more elastic than both the transition layer and the glass-like layer.

The first layer can also be described as having some type of texture. In some embodiments, texture analysis, atomic force microscopy (AFM), confocal microscopy or the like can be utilized to analyze the texture of the first layer. The first layer is generally smoother than both the transition layer and the glass-like layer.

The first layer can also be described as having optical properties. In some embodiments, the optical properties can be measured using a UV-Visible-Near Infrared (UV-Vis/NIR) spectrometer for example. Illustrative properties can include refractive index (n) and absorption index (k) for example. The first layer generally has a lower refractive index than both the transition layer and the glass-like layer. Optical properties such as haze and antireflective (AR) properties of the first layer could also be considered and/or measured.

The first layer can also be described as having a glass transition temperature (Tg) or a Tg range. The Tg of a material can be measured using dynamical mechanical analysis for example. The first layer generally has a broader and lower Tg than both the transition layer and the glass-like layer.

The first layer can also be described as being somewhat flowable. The ability of a material to flow can be measured using any of a number of various rheological methods including dynamic mechanical means (DMA). The first layer is generally more flowable than both the transition layer and the glass-like layer.

The first layer can also be described by its thickness. A desired thickness of the first layer can depend at least in part on the application for which the composite structure is being used, the material of the first layer, the structure on which the first layer was formed or deposited, optional processes that may be being carried out on the composite structure after formation, other considerations, or combinations thereof. In some embodiments, a first layer can have a thickness not less than 100 nm, not less than 2 micrometers, or not less than 5 micrometers. In some embodiments, a first layer can have a thickness not greater than 100 mils (1 mil equals 0.001 inch or 0.0254 mm), not greater than 50 mils, not greater than 200 micrometers, or not greater than 100 micrometers.

### Transition Layer

Composite structures described herein also include a transition layer. As seen from FIG. 1, the transition layer 120 is located between the first layer 110 and the glass-like layer 130. The transition layer 120 has a first surface 121 and an opposing surface or second surface 122. The first layer 110 is contiguous with the first surface 121 of the transition layer 120 and the glass-like layer 130 is contiguous with the second surface 122 of the transition layer 120. The transition layer can be described as having been formed from the first layer, or material making up the first layer. The transition layer can be described as a graded layer whose composition progresses from substantially that of the first layer 110 at the first surface 121 to substantially that of the glass-like layer 130 at the second surface 122.

The transition layer and the glass-like layer are formed by plasma treating the first layer 110 or the material of the first layer, an upper surface or upper portion of the first layer, or a precursor first layer. As the plasma treatment begins, the transition layer is formed first from material of the precursor first layer and then at least a portion of the transition layer is converted to the glass-like layer, so that the entire composite structure is formed from the original deposited material (e.g., a precursor first layer). Although not relied upon, it is thought that the plasma treatment is replacing carbons bonded to silicon's with oxygen atoms. The transition layer is just that, a transition from the material of the first layer to the material of the glass-like layer. As such, it contains both components of the material of the first layer and components of material of the glass-like layer. Closer to the first surface (121 in FIG. 1) of the transition layer, the material will be more like the first layer and closer to the second layer (122 in FIG. 1) of the transition layer, the material will be more like the glass-like layer.

The transition layer can also be described by its carbon to oxygen ratio (C:O). Generally, the transition layer includes more oxygen than the first layer but less than the glass-like layer. Similarly, the transition layer includes less carbon than the first layer but more than the glass-like layer. The value for carbon in a C:O ratio normalized by the amount of oxygen of the transition layer is therefore lower than that of the first layer that it was formed from but higher than that of the glass-like layer formed thereon or from it. The C:O ratio of the transition layer varies from one surface thereof to the other. In some embodiments, the C:O ratio of the transition layer can be measured, for example using XPS. In some embodiments, the C:O ratio of the transition layer can vary from 0.1 to 0.8 carbon to 1 oxygen (e.g., of atomic percentages as measured by XPS). In some embodiments, the transition layer can have a C:O ratio from 0.12 to 0.75 carbon to 1 oxygen (e.g., of atomic percentages as measured by XPS).

The transition layer can also be described by its hardness or elasticity. The transition layer will be harder than the first layer but softer than the glass-like layer. Similarly, the transition layer will be less elastic than the first layer but more elastic than the glass-like layer. Hardness or elasticity can be measured various ways, but the same method and procedure should be used to compare the hardness and/or elasticity of the first layer, the transition layer and the glass-layer.

The transition layer can also be described as having some type of texture. In some embodiments, texture analysis, atomic force microscopy (AFM), confocal microscopy or the like can be utilized to analyze the texture of the transition layer. The transition layer is generally less smooth than the first layer and more smooth than the glass-like layer.

The transition layer can also be described as having optical properties. In some embodiments, the optical properties can be measured using a UV-Visible-Near Infrared (UV-Vis/NIR) spectrometer for example. Illustrative properties can include refractive index (n) and absorption index (k) for example. The transition layer generally has a higher refractive index than the first layer and a lower refractive index than the glass-like layer. Optical properties such as haze and antireflective (AR) properties of the transition layer could also be considered and/or measured.

The transition layer can also be described as having a glass transition temperature (Tg) or a Tg range. The Tg of a material can be measured using dynamical mechanical analysis for example. The transition layer generally has a narrower Tg than the first layer and a broader Tg range than the glass-like layer. The transition layer generally has a higher Tg than the first layer and a lower Tg than the glass-like layer.

The transition layer can also be described as having a level of flowability. The ability of a material to flow can be measured using any of a number of rheological methods for example. The transition layer is generally less flowable than the first layer and more flowable than the glass-like layer.

The transition layer can also be described by the thickness thereof. Because of the nature of forming the transition layer and the glass-like layer, the exact delineation between the transition layer and glass-like layer can be considered somewhat arbitrary. It should also be noted that the thickness of the transition layer can be controlled, at least in part by the plasma treatment conditions (e.g., pressure of gases, time of treatment, etc.). However, in some embodiments, the transition layer can be described as having a thickness that is not greater than 1 micrometer (μm), in some embodiments not greater than 500 nanometers (nm), in some embodiments not greater than 200 nm, or in some embodiments not greater than 100 nm. In some embodiments, the transition layer can be described as having a thickness that is not less than 1 nm, or in some embodiments not less than 5 nm. In some embodiments, a thicker transition layer may be more advantageous than a thinner transition layer for increased interlayer adhesion.

Composite structures described herein also include a glass-like layer. As seen in FIG. 1, the glass-like layer 130 is disposed on top of the transition layer 120, more specifically on top of the second surface 121 of the transition layer 120. The glass-like layer can be described as being contiguous with the second surface 122 of the transition layer 120. The glass-like layer was formed from the first layer, the transition layer, or some combination thereof. As discussed above, the transition layer and the glass-like layer are formed by plasma treating the first layer 110 or a precursor first layer. As the plasma treatment begins, the transition layer is formed first and then at least a portion of the transition layer is converted to the glass-like layer, so that the entire composite structure is formed from originally deposited material of the first layer (e.g., a precursor first layer). Although not relied upon, it is thought that the plasma treatment is replacing carbons bonded to silicon's with oxygen atoms.

The glass-like layer has at least some properties similar to those of glass. For example, the glass-like layer has a lower contact angle (e.g., static water contact angle) than that of the first layer from which it was formed. The glass-like layer may have some barrier properties, e.g. barrier to at least some liquids, at least some gasses, or combinations thereof. In some embodiments, the glass-like layer may have at least some SiO_{4/2} (e.g., glass) within the layer.

The glass-like layer can be described by its carbon to oxygen ratio (C:O). Generally, the glass-like layer includes more oxygen than both the first layer and the transition layer. Similarly, the glass-like layer includes less carbon than both the transition layer and the first layer. The value for carbon in a C:O ratio normalized by the amount of oxygen in the glass-like layer is therefore lower than that of both the first layer and the transition layer that it was formed from. In some embodiments, the value for carbon in a C:O ratio normalized by the amount of oxygen in the glass-like layer can be measured, for example using XPS. In some embodiments, the C:O ratio of the glass-like layer approaches zero. In some embodiments, the normalized C:O ratio of the glass-like layer is from 0 to 0.1 carbon to 1 oxygen (e.g., atomic percentage as measured by XPS). In some embodiments, the normalized C:O ratio of the glass-like layer is from 0.001 to 0.009 carbon to 1 oxygen (e.g., atomic percentage as measured by XPS). In some embodiments, the normalized C:O ratio of the glass-like layer is from 0.01 to 0.08 carbon to 1 oxygen (e.g., atomic percentage as measured by XPS).

The glass-like layer can also be described by its hardness or elasticity. The glass-like layer will be harder than both the transition layer and the first layer. Similarly, the glass-like layer will be less elastic than both the transition layer and the first layer. Hardness or elasticity can be measured various ways, but the same method and procedure should be used to compare the hardness and/or elasticity of the first layer, the transition layer and the glass-layer.

The glass-like layer can also be described as having some type of texture. In some embodiments, texture analysis, atomic force microscopy (AFM), confocal microscopy or the like can be utilized to analyze the texture of the glass-like layer. The glass-like layer is generally less smooth than both the transition layer and the glass-like layer.

The glass-like layer can also be described as having optical properties. In some embodiments, the optical properties can be measured using a UV-Visible-Near Infrared (UV-Vis/NIR) spectrometer for example. Illustrative properties can include refractive index (n) and absorption index (k) for example. The glass-like layer generally has a higher refractive index than both the transition layer and the first layer. Optical properties such as haze and antireflective (AR) properties of the first layer could also be considered and/or measured.

The glass-like layer can also be described as having a glass transition temperature (Tg) or a Tg range. The Tg of a material can be measured using dynamical mechanical analysis for example. The glass-like layer generally has a narrower and higher Tg than both the transition layer and the first layer.

The glass-like layer can also be described by its ability or inability to flow. The ability of a material to flow can be measured using any of a number of rheological methods for example. The glass-like layer is generally less flowable than both the transition layer and the first layer. A composite structure with such features of flowability may be useful in the area of optics for instance. Silicone containing pressure sensitive adhesives are often employed in optics (such as light guiding applications) because of their low refractive indices, while also providing bonding to adjacent optical surfaces. However, it may be advantageous if some optical features, such as extraction features, could remain adhesive free. The ability to form the glass-like layer from a PSA composition could be used to prevent the inflow of the adhesive into areas (e.g., extraction features), yet allow for some bonding to occur as it cracks during the traditional application of pressure to the surface during bonding steps.

The glass-like layer can also be described by the thickness thereof. Because of the nature of forming the transition layer and the glass-like layer, the exact delineation between the transition layer and glass-like layer can be considered somewhat arbitrary. It should also be noted that the thickness of the glass-like layer can be controlled, at least in part by the plasma treatment conditions (e.g., pressure of gases, time of treatment, etc.). However, in some embodiments the glass-like layer can be described as having a thickness that is not less than 500 nm, in some embodiments not less than 250 nm, in some embodiments not less than 200 nm, or in some embodiments not less than 150 nm. In embodiments where it is desired to have a thicker glass-like layer, the glass-like layer or a layer that is even closer to glass can be deposited thereon using plasma deposition by adding a silicon source or (in embodiments where the plasma already included a silicon source) more of a silicon source to the plasma. It should also be noted that the thicker the glass-like layer is, the better its barrier properties are likely to be. It may also be advantageous, in order to further increase barrier properties thereof, to deposit/form the glass-like layer/add on layers in more than one step (e.g., in order to not propagate breaks or pin holes through the layer).

The glass-like layer can also be described by its stability. In some embodiments, the glass-like layer maintains its stability for at least 3 days, in some embodiments at least 5 days, in some embodiments at least 10 days. By maintain its stability it is meant that the glass-like layer has less rearrangement of its structure or less redevelopment of freedom of motion in the molecules (e.g., has less hydrophobic recovery or more flexible layer). In some embodiments, the stability can be measured or monitored by the contact angle, for example, the static water contact angle. In some embodiments, the glass-like layer has a static contact angle with water that doesn't change more than 30°+10° over at least 3 days, at least 5 days, or at least 10 days after formation thereof. In some embodiments, the glass-like layer has a static contact angle with water that doesn't change more than 30°+5° over at least 3 days, at least 5 days, or at least 10 days after formation thereof. In some embodiments, the glass-like layer can have a static contact angle with water that is not more than 95° at least 3 days, at least 5 days, or at least 10 days after formation thereof.

The glass-like layer can also be described as being tack free, in opposition to the first layer which can be described as tacky. The glass-like layer can also be described as not having adhesive properties (e.g., pressure sensitive adhesive properties) as opposed to the first layer which has adhesive properties (e.g., pressure sensitive adhesive properties). It should be noted that if pressure is applied to a composite structure, the glass-like layer may be broken, exposing previously covered first layer and transition layer. Such exposed first layer and transition layer may have adhesive properties, although the broken glass-like layer still does not. The glass-like layer also remains tack free over time, e.g., at least 3 days, at least 5 days, or at least 10 days after formation.

The glass-like layer can also be described as being unable to flow under normal ambient conditions, for example, as opposed to the first layer which can be described as flowable.

### Methods

Disclosed herein are also methods of forming a structure that includes a glass-like layer or disclosed composite structures. In some embodiments, such methods can include a step of depositing a layer that includes a silicone block copolymer and plasma treating that layer to convert at least some of the silicone block copolymer to a glass-like layer. Although not relied upon, it is thought that the plasma treatment is replacing at least some of the carbons bonded to the silicon's in the silicone block copolymer with oxygen atoms. The step of plasma treatment may be more specifically described as forming a transition layer and a glass-like layer. In some embodiments, the plasma treatment could first be forming a transition layer and subsequent plasma treatment could then be converting some of that transition layer into a glass-like layer.

Disclosed methods can include a step of depositing material of the first layer, or stated another way forming a precursor first layer. In the context of the methods of forming, the material of the first layer will be considered a precursor first layer until it is plasma treated, at which time it will be considered a first layer. Generally, the difference between the precursor first layer and the first layer is that some of the material of the precursor first layer has been utilized to form the transition layer and the glass-like layer. The precursor first layer includes material such as were described above for the components of the first layer. Methods discussed above of forming the first layer can be utilized herein to form the precursor first layer. As some of the material of the precursor first layer will ultimately be converted into the transition layer and the glass-like layer, it may be useful to deposit the precursor first layer slightly thicker than it is desired that the final first layer be. The amount of material consumed from the precursor first layer can depend, at least in part on conditions of plasma treatment, etc.

Various properties or characteristics of the plasma treatment can be controlled and/or modified to vary the transition layer and/or glass-like layer. For example, the components of the plasma can be modified (e.g., identities of components, amounts of components, nature of introduction of the components, etc.), the atmosphere in which the plasma treatment is carried out can be modified (e.g., pressure within the chamber, temperature within the chamber, etc.), the length of the plasma treatment can be modified, the conditions of forming the plasma can be modified (e.g., power, duty cycle of on and off times, etc.), other parameters not specifically discussed herein, or any combination thereof.

In some embodiments, the plasma treatment can be done in the presence of oxygen (O₂). In some embodiments, the plasma treatment may be undertaken in an atmosphere that includes some level of O₂. In some embodiments, the plasma itself may be formed from O₂ (and optionally other components). In some embodiments, the plasma may also contain components other than 02. The components other than 02 can be from liquids, gases or both. In some embodiments, the plasma may contain a source of silicon (Si), or a Si containing component. In some embodiments, a first layer can first be treated with oxygen only plasma and then subsequently treated with an oxygen+non-oxygen component plasma. In such embodiments, either or only one of the plasma treatment steps can be forming the transition layer and glass-like layer. In some embodiments, a first layer can first be treated with O₂ plasma and then treated with an O₂+Si containing component plasma. Introduction of silicon into the plasma may function to deposit a layer that has properties similar to a glass-like layer and/or actual glass. As such, plasma treatment with an O₂ only plasma followed by subsequent treatment with O₂+silicon plasma could form a transition layer and glass-like layer from a first layer and then subsequently form additional glass-like material or material that has properties similar to glass (which may or may not be substantially the same as the glass-like layer formed from the first layer).

In some embodiments, the plasma treatment can be carried out for not less than 5 seconds, in some embodiments not less than 30 seconds, or in some embodiments not less than 60 seconds. Plasma treatments configured to obtain effects similar to those descried herein and similar to the specific plasma treatment protocols utilized in the examples can also be utilized, even if non-similar plasma treatment times are not utilized.

Any plasma generating system or machine can be utilized to carry out disclosed methods. An illustrative embodiment of a particular system can include a commercial batch plasma system (Plasmatherm Model 3032) configured for reactive ion etching (RIE) with a 26-inch lower powered electrode and central gas pumping. The chamber can be pumped by a roots blower (Edwards Model EH1200) backed by a dry mechanical pump (Edwards Model iQDP80). RF power can be delivered by a 5 kW, 13.56 Mhz solid-state generator (RFPP Model RF50S0) through an impedance matching network. The system can have a nominal base pressure of 5 mTorr. The flow rates of the gases can be controlled by MKS flow controllers.

An illustrative method for forming a glass-like layer utilizing the above illustrative system, for example, may, but need not, also include the following specific steps, processes, or details. Substrates for surface modification or deposition can be either placed on the lower powered electrode or elevated out of the sheath region using glass plates. After inserting the sample, the reactor chamber can be pumped down to a base pressure of less than 1.3 Pa (10 mTorr). The plasma treatment is accomplished by feeding the appropriate types of gases and/or liquid precursors at the prescribed flow rates. Once the flows are stabilized, the rf power can be applied to the electrode to generate the plasma. The plasma can be left on for a described amount of time. Following the treatment, the RF power and the gas supply can be stopped and the chamber can be returned to atmospheric pressure.

In some embodiments one or more steps can be carried out between the deposition of the precursor first layer and the plasma treatment thereof. For example, the precursor first layer could be structured. Structure can be formed on or in the precursor first layer by embossing, printing, photolithography, abrading or mechanically cutting for example. Structure can also be imparted to a precursor first layer by utilizing an additive to provide such structure. In some embodiments it may be desirable to impart a microstructured surface to one or both major surfaces of the precursor first layer. It may be desirable to have a microstructured surface on at least one surface of the precursor first layer to aid air egress during lamination, if applicable. If it is desired to have a microstructured surface on one or both surfaces of the precursor first layer, the coating or film may be placed on a tool or a liner containing microstructuring. The liner or tool can then be removed to expose a precursor first layer having a microstructured surface. Various structures and/or patterns may be formed in or on the precursor first layer. For example, patterns that impart optical properties could be formed in the precursor first layer.

After plasma treatment to form a glass-like layer, any additional steps or processes can be carried out on the composite structure. For example, additional plasma treatment steps may be carried out to deposit additional material on the glass-like layer. Such additional materials may have properties similar to the glass-like layer, may have properties similar to glass, or may have properties unrelated to glass. In some embodiments, an additional precursor first layer may be deposited on the glass-like layer. The additional precursor first layer may then be plasma treated to form a multilayer composite structure; the first layer may be adhesive in nature and may be utilized to adhere to the composite structure to some other article or structure; or any combination thereof. In some embodiments, a material not previously utilized in disclosed methods may be deposited on the glass-like layer. For example, a material with barrier properties may be deposited on the glass-like layer. The material with barrier properties may have different, better, or both (for example) barrier properties than the glass-like layer upon which it is being deposited. In some embodiments, virtually any material may be deposited or formed on the glass-like layer.

After plasma treatment to form a glass-like layer, the composite structure could also be utilized to form a laminate with some other structure. For example, the first layer, which may be an adhesive, e.g., a pressure sensitive adhesive, could have been formed on a release liner, the release liner could be removed and the composite structure adhered to some other composite structure or article. In some other embodiments, the composite structure could be mechanically cut, so as to form two or more portions of composite structure and the at least two portions of composite structure could be used to form a laminate with itself, and optionally the process may be repeated, or any other process may be carried out.

Composite structures disclosed herein can be formed by themselves or on any other surface, structure or article. In some embodiments, composite structures can be formed (as discussed above) and then transferred to some other article. In such embodiments, the composite structure can be formed on a surface or substrate, for example a release liner, and then the composite structure could be transferred to the secondary surface, structure or article. In some embodiments, composite structures can be formed directly on the secondary surface, structure or article. Forming the composite structure on a surface and transferring it to a secondary surface may be advantageous when the ultimate surface, substrate or article to which it will be transferred (the secondary surface) is not amenable to plasma treatment or the conditions associated therewith for example. In embodiments where the composite structure is formed on a secondary surface, structure or article, the substrate can be either flexible or rigid. An advantage of disclosed composite structures is that the composite structure remains at least somewhat flexible even though the glass-like layer is contained. This can offer numerous advantages for use of the composite structure. Another advantage of disclosed composite structures is that they may offer at least some barrier properties. Therefore, applying the composite structures on surfaces or forming the composite structures on surfaces may be a method of imparting barrier properties to underlying structures.

Composite structures, materials associated therewith, or a combination thereof can also be utilized to adhere two structures together. In some embodiments, material of a first layer, e.g., a silicone block copolymer containing adhesive, e.g., a pressure sensitive adhesive, can be utilized to adhere two structures together. For the sake of illustration only: a layer of silicone block copolymer pressure sensitive adhesive can be deposited on a release liner and the surface of the PSA can be laminated to a surface (for the sake of example a glass slide). This first step could also be accomplished by applying the PSA directly to the surface. Then, a second surface (for the sake of example a second glass slide) could be laminated to the exposed surface of the PSA. The exposed edge of the PSA, e.g., the edge of the PSA at one or the other of the ends (or both) of the surface/PSA/surface laminate, can then be plasma treated in order to form a glass-like layer at one or the other (or both) ends of the laminate. This illustrative construct shows how the composite structure and method of forming the composite structure could be utilized to both adhere two surfaces and then convert any of the exposed PSA into a glass-like layer. This could be advantageous because it could render the exposed PSA non-tacky (e.g., it would not have adhesive properties, e.g., pressure sensitive adhesive properties), it could afford barrier properties on all four surfaces (two because of the laminated surfaces themselves and two by converting the exposed PSA into glass-like layers), or any combination thereof.

Examples of substrates upon which the composite structure could be formed (or even ultimately transferred to) include, for example rigid substrates include glass sheets, rigid polymeric sheets and display surfaces. In some embodiments, composite structures can be formed on one or more surfaces of a primary structure. The primary structure can include virtually any article, device or substrate where disclosed composite structures could be useful. Examples of applications where composite structures may be useful and illustrative primary structures can include, for example, electronic devices, optics and optical devices such as graphics display devices, solar cell devices, or otherwise. Examples of devices that may utilize such laminations include such devices as portable and non-portable information display devices including personal digital assistants, cell phones, touch-sensitive screens, wrist watches, car navigation systems, global positioning systems, television screens (e.g., OLEDs), computer monitors, notebook computer displays, electroluminescent displays, and the like. Other devices on which composite structures disclosed herein can be utilized, e.g., other primary structures, can include windows, microfluidics, sensors, photolithographics, electroluminescent lighting, packaging, and adhesives. It has been observed that bonding of the rigid cover to the display screen, and thus eliminating any air gap between them, provides improvement in the quality of the displayed image.

### Illustrative Disclosed Embodiments are Provided Below.

Some illustrative embodiments can include a composite structure comprising: a first layer comprising a silicone block copolymer; a transition layer, the transition layer having a first surface contiguous with the first layer and a second opposing surface, the transition layer formed from the silicone block copolymer of the first layer; and a glass-like layer contiguous with the second surface of the transition layer, at least a portion of the glass-like layer formed from the transition layer.

Such composite structures wherein the silicone block copolymer is a condensation silicone block copolymer. Such composite structures, wherein the silicone block copolymer comprises silicone polyoxamide copolymers, silicone polyurea copolymers, or combinations thereof. Such composite structures, wherein the silicone block copolymer is an adhesive. Such composite structures, wherein the silicone block copolymer is a pressure sensitive adhesive. Such composite structures, wherein the silicone block copolymer comprises silicone polyoxamide copolymers, silicone polyurea copolymers, or combinations thereof; and tackifying resin. Such composite structures, wherein the tackifying resin comprises MQ tackifying resins. Such composite structures, wherein the first layer comprises:

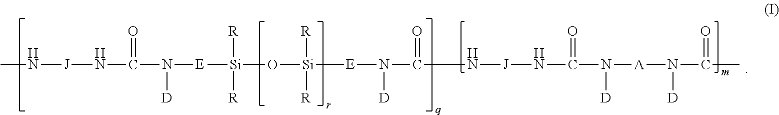

wherein

each R is a moiety that, independently, is an alkyl moiety, having 1 to 12 carbon atoms, and may be substituted with, for example, trifluoroalkyl or vinyl groups, a vinyl radical or higher alkenyl radical represented by the formula R²(CH₂)ₐCH═CH₂ wherein R² is —(CH₂)_{b}— or —(CH₂)_{c}CH═CH— and a is 1, 2 or 3; b is 0, 3 or 6; and c is 3, 4 or 5, a cycloalkyl moiety having from 6 to 12 carbon atoms and may be substituted with alkyl, fluoroalkyl, or vinyl groups, or an aryl moiety having from 6 to 20 carbon atoms and may be substituted with, for example, alkyl, cycloalkyl, fluoroalkyl and vinyl groups or R is a perfluoroalkyl group, or a fluorine-containing group, or a perfluoroether-containing group; each J is a polyvalent radical that is an arylene radical or an aralkylene radical having from 6 to 20 carbon atoms, an alkylene or cycloalkylene radical having from 6 to 20 carbon atoms; each E is a polyvalent radical that independently is an alkylene radical of 1 to 10 carbon atoms, an aralkylene radical or an arylene radical having 6 to 20 carbon atoms; each D is selected from the group consisting of hydrogen, an alkyl radical of 1 to 10 carbon atoms, phenyl, and a radical that completes a ring structure including A or E to form a heterocycle; each A is a polyvalent radical selected from the group consisting of alkylene, aralkylene, cycloalkylene, phenylene, heteroalkylene, and mixtures thereof; m is a number that is 0 to 1000; q is a number that is at least 1; and r is a number that is at least 10. Such composite structures, wherein the first layer comprises:

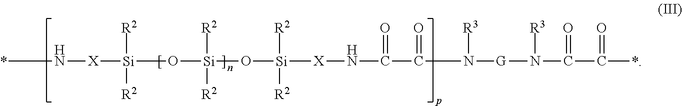

wherein each R² is independently an alkyl, haloalkyl, aralkyl, alkenyl, aryl, or aryl substituted with an alkyl, alkoxy, or halo, wherein at least 50 percent of the R² groups are methyl; each X is independently an alkylene, aralkylene, or a combination thereof; G is a divalent group that is the residue unit that is equal to a diamine of formula R³HN-G-NHR³ minus the two —NHR³ groups, where R³ is hydrogen or alkyl or R³ taken together with G and the nitrogen to which they are both attached forms a heterocyclic group; n is independently an integer of 40 to 1500; and the subscript p is an integer of 1 to 10. Such composite structures, wherein the first layer has an oxygen normalized carbon to oxygen ratio, the transition layer has an oxygen normalized carbon to oxygen ratio and the glass-like layer has an oxygen normalized carbon to oxygen ratio, and the oxygen normalized carbon to oxygen ratio of the first layer is higher than both the transition layer and the glass-like layer. Such composite structures, wherein the oxygen normalized carbon to oxygen ratio of the transition layer is higher than that of the glass-like layer. Such composite structures, wherein the oxygen normalized carbon to oxygen ratio of the transition layer decreases from the first layer to the second layer. Such composite structures, wherein the first layer is more elastic than both the transition layer and the glass-like layer. Such composite structures, wherein the transition layer is more elastic than the glass-like layer. Such composite structures, wherein the glass-like layer is harder than both the transition layer and the first layer. Such composite structures, wherein the transition layer is harder than the first layer. Such composite structures, wherein the transition layer and the glass-like layer were formed by plasma treating material of the first layer. Such composite structures, wherein the transition layer has a thickness from 1 nm to 200 nm. Such composite structures, wherein the thickness of the transition layer, the thickness of the glass-like layer, or both are at least somewhat controlled by the total time of plasma treatment. Such composite structures, wherein the glass-like layer has a static contact angle with water of not greater than 95°. Such composite structures, wherein the glass-like layer substantially maintains the contact angle for at least 10 days. Such composite structures, further comprising at least a second set of: first layer, transition layer and glass-like layer. Such composite structures, wherein the second first layer is adjacent the first glass-like layer. Such composite structures, further comprising an additional layer adjacent the first layer or adjacent the glass-like layer. Such composite structures, further comprising a barrier film adjacent the first layer opposite the transition layer. Such composite structures, further comprising a barrier film adjacent the glass-like layer opposite the transition layer. Such composite structures, further comprising an organic light emitting diode (OLED) structure, wherein the first layer, transition layer and glass-like layer are adjacent the display surface of the OLED. Such composite structures, wherein the first layer is contiguous with a junction of two substrates. Such composite structures, wherein at least one of the two substrates comprise glass. Such composite structures, wherein the first layer is contiguous with additional silicone block copolymer material. Such composite structures, wherein the additional silicone block copolymer material adheres two articles together. Such composite structures, wherein the two articles are two rigid substrates. Such composite structures, wherein the two rigid substrates are optical substrates. Such composite structures, wherein the glass-like layer has barrier properties. Such composite structures, wherein the glass-like layer has gas barrier properties, water barrier properties, or both.

Some illustrative embodiments can include methods of forming a structure comprising a glass-like layer, the methods comprising: depositing a precursor first layer, the precursor first layer comprising a silicone block copolymer; and plasma treating the precursor first layer to convert at least some of the silicone block copolymer to the glass-like layer.

Such methods, wherein the step of plasma treating is done at least in the presence of oxygen. Such methods, wherein the step of plasma treating is done with an oxygen containing plasma. Such methods, wherein the step of plasma treating is done in an atmosphere containing oxygen. Such methods further comprising structuring the precursor first layer before it is plasma treated. Such methods, wherein the step of structuring the precursor first layer comprises molding the first layer, embossing the first layer, or combinations thereof. Such methods, wherein the plasma treatment is carried out while a force is being applied to the precursor first layer. Such methods, wherein the force is removed after the plasma treatment. Such methods, wherein the structure is printed after the plasma treatment. Such methods further comprising depositing one or more additional materials on the glass-like layer. Such methods, wherein the one or more additional materials comprises a second precursor first layer comprising a silicone block copolymer. Such methods further comprising plasma treating the second precursor first layer to form a second glass-like layer. Such methods, wherein the precursor first layer is deposited on a barrier film. Such methods, wherein the precursor first layer is deposited on a structure comprising an organic light emitting diode (OLED) structure. Such methods further comprising mechanically cutting the composite structure to form a first composite portion and a second composite portion and adhering the first and second composite portions together. Such methods further comprising repeating the cutting and adhering steps. Such methods further comprising adhering the composite structure to an article via the precursor first layer.

Some illustrative articles can include articles comprising: a primary structure; and a composite structure, the composite structure disposed on at least some surface of the primary structure, the composite structure comprising: a first layer comprising a silicone block copolymer; a transition layer, the transition layer having a first surface contiguous with the first layer and a second opposing surface, the transition layer formed from the silicone block copolymer of the first layer; and a glass-like layer contiguous with the second surface of the transition layer, at least a portion of the glass-like layer formed from the transition layer.

Such articles, wherein the primary structure comprises an electronic device. Such articles, wherein the primary structure is selected from: windows, microfluidics, sensors, photolithographics, electroluminescent lighting, packaging, and adhesives. Such articles, wherein the primary device is a display device. Such articles, wherein the display device is an organic light emitting diode (OLED) display device.

The following non-limiting examples serve to describe more fully the manner forming the composite structures and the composite structures themselves. It is understood that these examples in no way serve to limit the scope of this disclosure or claims that follow, but rather are presented for illustrative purposes.

### EXAMPLES

All parts, percentages, ratios, etc. in the examples are by weight, unless noted otherwise. Solvents and other reagents used were obtained from Sigma-Aldrich Corp., St. Louis, Mo. unless specified differently.

### Materials List

| Abbreviation | Source |
|---|---|
| L1 | Liner, fluorosilicone-coated PET commercially available from Siliconature USA, |
| | LLC, Chicago, IL, as SILFLU MD07. |
| L2 | Liner, fluorosilicone-coated polyester film commercially available from |
| | Siliconature, USA, LLC, Chicago, IL, As SILFLU M117. |
| R1 | Resin, commercially available from Wacker Chemie AG as MQ-RESIN |
| | POWDER 803 TF. |
| ADH1 | Adhesive, Silicone polyoxamide as described in Example 25 (with elastomer/MQ |
| | ratio of 90/10) of U.S. Pat. No. 7,981,995 (Hays) 51 micrometers thick on primed |
| | PET (HOSTAPHAN 3SAB primed polyester film available from Mitsubishi |
| | Polyester Film Inc, Greer, S.C.) |
| ADH2 | Two part silicone adhesive commercially available from Nusil Technology |
| | LLC, Henrico, VA, as LS6140. |
| ADH3 | Two-part silicone encapsulant available from Smooth-On, Inc. East Texas, PA, as |
| | SOLARIS. |
| FILM1 | Transparent Film Dressing available from 3M Company, St. Paul, MN as |
| | TEGADERM 1616. |
| MARKER | Marking pen commercially available from BIC Consumer Products USA, Shelton, |
| | CT as BRITE LINER Green. |
| L4 | Structured Liner, the baseliner as described in Example 14 preparation of Liner J |
| | of U.S. Pat. Pub. No. 20130251961. This film is heat embossed with a tool to |
| | generate structure in the film with the dimensions of 400 micron edge hexagons |
| | with a pitch of 850 microns. The raised regions have a height of 4.9 microns. |
| L5 | Structured Liner, the base liner as described in Example 14 preparation of Liner J |
| | of U.S. Pat. Pub. No. 20130251961.. This film is heat embossed with a tool to |
| | generate structure in the film with the dimensions 350 micron wide lines with a |
| | pitch of 1000 microns. The raised regions have a height of 3.5 microns. |
| AM1 | Acrylate Monomer, Aliphatic Urethane Hexaacrylate, commercially available |
| | from Allnex, Smyrna, GA as “EBECRYL 8301-R”. |
| AM2 | Acrylate Monomer, Hexanediol Diacrylate, commercially available from |
| | Ciba/BASF, Hawthorne, NY as “LAROMER” HDDA. |
| AM3 | Acrylate Monomer, Pentaerythritol Tetracrylate, commercially available from |
| | Sigma-Aldrich, St. Louis, MO as “PETA 408263”. |
| PI1 | Photoinitiator, 70:30 blend of oligo [2-hydroxy-2-methyl-1-[4-(1-methylvinyl) |
| | phenyl] propanone] and 2-Hydroxy-2-methyl-1-phenyl-1-propanone, |
| | commercially available from Esstech, Inc., Essington, PA as “PL100” |
| R2 | A 60% solids solution in toluene MQ Resin commercially available from |
| | Momentive Performance Materials Inc. Waterford, NY as SR545. |
| D1 | PDMS diamine 41,000 (an approximately 41,000 molecular weight |
| | polydimethylsiloxane diamine prepared as described in Example 4 of U.S. Pat. |
| | No. 6,534,615) |
| P1 | Polyamine organic diamine, commercially available from DuPont, Wilmington, |
| | DE, as DYTEK A. |
| H12MDI | methylenedicyclohexylene-4,4′-diisocyanate, commercially available from Bayer, |
| | Pittsburgh, PA, as DESMODUR W |

### Example Preparation

Example 1 (E1 in Tables) was a 5 micron thick layer silicone polyoxamide PSA. Formed from a 41K PDMS diamine (an approximately 41,000 molecular weight polydimethylsiloxane diamine prepared as described in Example 4 of U.S. Pat. No. 6,534,615) that was used to prepare a PSA per Example 5 in U.S. Pat. No. 7,371,464 with the changes such that the MQ resin used was R1. The silicone polyoxamide to R1 ratio was 50:50. The solvents used were IPA and toluene in a ratio of 30:70. The resulting solution final % solids was 20% prior to coating. This silicone adhesive solution was die coated onto a liner, L1. A 72 deg C. solvent oven was used to remove the solvent and then liner L2 was laminated to the dried surface. This Example was further processed by removing liner L1, making evaluations and then further processing using the Plasma Treatment described below.

Example 2 (E2 in Tables) was a 2 micron thick layer of silicone polyurea PSA. Formed from an elastomer containing a molar ratio of silicone diamine/polyamine-1/H12MDI of 1/1/2 was formulated with 50 weight % R2. The formulation was prepared by placing 14.86 parts D1 in a glass reactor with 0.05 parts P1 39.00 parts toluene and 21.00 parts 2-propanol. 0.23 parts H12MDI was added to the solution, the mixture was stirred at room temperature for two hours and became viscous. To this was added 25.00 parts of R2. The resulting solution was solvent coated onto a release liner and dried for 10 minutes at 70.degree. C. This silicone adhesive solution was die coated onto a liner, L1 a 70 deg C. solvent oven was used to remove the solvent and then liner L2 was laminated to the dried surface. This Example was further processed by removing liner L1, making evaluations and then further processing using the Plasma Treatment described below.

Comparative Example 1 (C1 in Tables) was a 25 micron thick coating of a two-part silicone adhesive. This silicone adhesive solution ADH2 was die coated onto a liner, L1 a 72 deg C. solvent oven was used to remove the solvent and then liner L2 was laminated to the dried surface. This Example was further processed by removing liner L1, making evaluations and then further processing using the Plasma Treatment described below.

Comparative Example 2 (C2 in Tables) was a 25 micron thick coating of a two-part silicone encapsulant. This silicone solution ADH3 was die coated onto a liner, L1 a 72 deg C. solvent oven was used to remove the solvent and then liner L2 was laminated to the dried surface. This Example was further processed by removing liner L1, making evaluations and then further processing using the Plasma Treatment described below.

Example 3 (E3 Hex and E3 Linear) were the silicone polyoxamide ADH1 that was printed with acrylate structures and laminated to structured (Hex and Linear) liners.

Acrylate Formulation: The printed structures are an acrylate formulation composed of 50 wt % AMI, 25 wt % AM2, and 25 wt % AM3 with 1 wt % PI1.

Printing Structures: Samples were prepared by printing the acrylate formulation described above on ADH1 using a FLEXI-PROOFER Flexographic printing unit (Weller Patents Development, Putney, London England). The anilox roll used was 4 BCM 700 lines/inch (1,778 lines/cm), hexagonal cells engraved at 60 degrees. A random circle stamp with a pitch of 150 microns and a diameter for the features of 30 microns was used. After printing the samples were cured in a LIGHTHAMMER 6 UV curing system with a D bulb (Heraeus Noblelight Fusion UV Inc., Gaitherburg, Md.). Curing took place at 100% power and 25 ft/min (7.6 m/min), 1 pass.

Adhesive Structuring: The printed structured side of the samples were then laminated to a structured liner. E3 Hex liner was L4. E3 Linear liner was L5. These Examples were further processed by removing liner L4 or L5 respectively, making evaluations and then further processing using the Plasma Treatment described below.

### Plasma Treatment

Examples (E1-E3 and C1, C2) were exposed to plasma according to the following general procedure: A surface layer bearing silane and siloxane groups was created on the PSA using a commercial batch plasma system (Plasmatherm Model 3032) configured for reactive ion etching (RIE) with a 26-inch lower powered electrode and central gas pumping. The chamber was pumped by a roots blower (Edwards Model EH1200) backed by a dry mechanical pump (Edwards Model iQDP80). RF power was delivered by a 5 kW, 13.56 Mhz solid-state generator (RFPP Model RF50S0) through an impedance matching network. The system has a nominal base pressure of 5 mTorr. The flow rates of the gases were controlled by MKS flow controllers. All film samples were tapped to lower powered electrode. The Edge Seal sample was elevated out of the sheath region using glass plates. After inserting the sample, the reactor chamber was pumped down to a base pressure of less than 1.3 Pa (10 mTorr). The plasma treatment was accomplished by feeding the appropriate types of gases and/or liquid precursors at the prescribed flow rates. One of the conditions used was 500 sccm of O₂ at 750 watts of rf power for 300 seconds. The other condition was 500 sccm of O₂ at 750 watts of rf power for 300 seconds, followed by deposition layer initiated at 25 sccm of O₂—SiMe₄ (tetramethyl silane) and 500 sccm of O₂ at 750 watts of rf power for 300 seconds. Once the flows were stabilized, the rf power was applied to the electrode to generate the plasma. The plasma was left on for a prescribed amount of time as detailed above. Following the treatment, the RF power and the gas supply were stopped and the chamber was returned to atmospheric pressure.

### Results

### Contact Angle as a Function of Time

Static water contact angles were measured at room temperature using a Kruss (Hamburg, Germany) DSA100 contact angle instrument (5 microliter drop delivered at 195 microliter per minute) on non-plasma treated and plasma treated samples. Mean values of five replicates are given (standard deviations in the range 0.5 to 5 degrees) in Table 1 below. These results show that E1 and E2 retained reduced contact angles (consistent with a more hydrophilic glassy surface) 10 days after plasma treatment, while the comparative samples have undergone hydrophobic recovery 10 days after plasma treatment.

TABLE 1

| | | O₂—SiMe₄ | O₂—SiMe₄ | O₂ | O₂ |
|---|---|---|---|---|---|
| | Untreated | conditions | Conditions | conditions | conditions |
| Sample | Substrates | (1 day) | (10 days) | (1 day) | (10 days) |
| E1 | 102 | 54 | 85 | 91 | 84 |
| E2 | 108 | — | 82 | — | 75 |
| C1 | 115 | 51 | 69 | 35 | 85 |
| C2 | 113 | 83 | 109 | 102 | 106 |

### XPS Surface Characterization

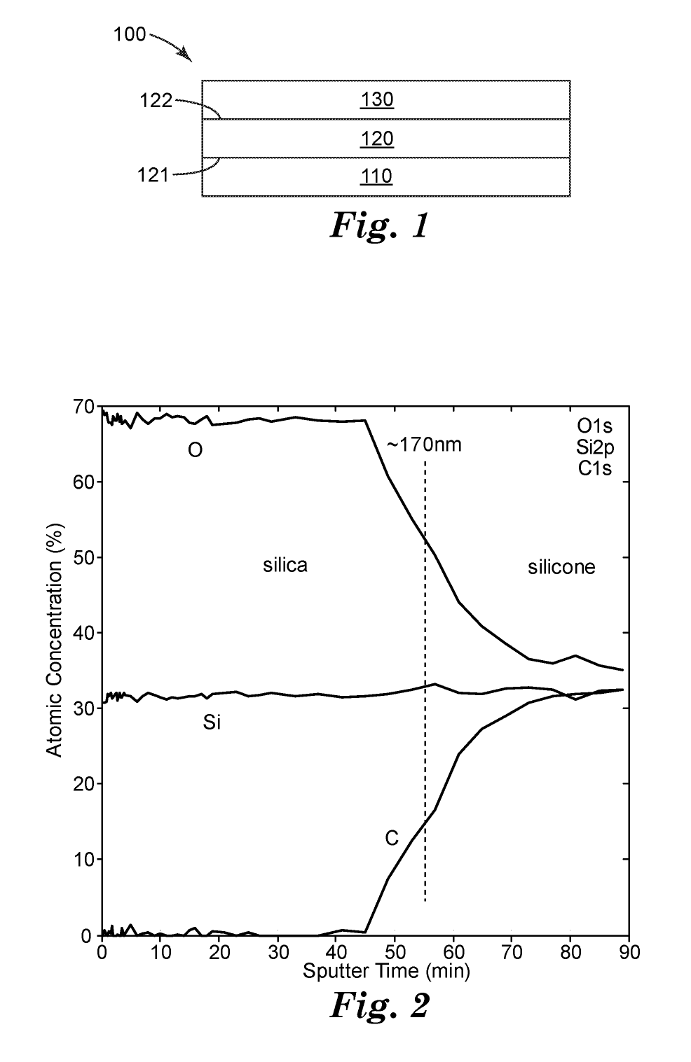

The surface of E1 and E2 after O₂ plasma treatment or after O₂—SiMe₄ plasma treatment was characterized by XPS (Physical Electronics Quantera II™) with sputtering (ion gun 2 keV Ar⁺, 3 mm by 3 mm raster) to determine the composition as a function of depth/sputter time. The surfaces were shown to have a glassy silicon dioxide composition with a gradient to the first layer composition over distances ranging from 10 to 170 nm from the surface. Table 2 generally describes the composite structure and Table 3 shows the XPS atomic percentages of Carbon (C), oxygen (O), and silicon (Si) and C:O (normalized to O) versus sputter time for E1 the graph of which can be seen in FIG. 2 (170 nm from surface (left) to end plateau/start of gradient layer (center-right)). Rows 49, 53, 57, 61, 65 and 69 of Table 3 indicate the transition layer.

TABLE 2

| Sample | O₂ conditions | O₂—SiMe₄ conditions |
|---|---|---|
| E1 | <10 nm | 170 nm Gradient |
| (5 micron) | (7 days) | (12 days) |
| E2 | <10 nm | 120 nm Gradient |
| | (7 days) | (7 days) |

TABLE 3

| | Carbon | Oxygen | Silicon | Normalized |
|---|---|---|---|---|
| Minutes | percentage | percentage | percentage | C:O |
| 0.25 | 0.0 | 69.3 | 30.7 | 0* |
| 0.50 | 0.6 | 68.7 | 30.7 | 0 |
| 0.75 | 0.1 | 69.0 | 30.9 | 0 |
| 1.00 | 0.0 | 68.1 | 31.9 | 0 |
| 1.25 | 0.6 | 67.8 | 31.7 | 0 |
| 1.50 | 0.2 | 67.8 | 32.1 | 0 |
| 1.75 | 1.2 | 67.5 | 31.3 | 0.01 |
| 2.00 | 0.0 | 68.6 | 31.4 | 0 |
| 2.25 | 0.0 | 68.1 | 31.9 | 0 |
| 2.50 | 0.0 | 68.0 | 32.0 | 0 |
| 2.75 | 0.0 | 68.9 | 31.1 | 0 |
| 3.00 | 0.0 | 67.9 | 32.1 | 0 |
| 3.25 | 0.0 | 68.6 | 31.4 | 0 |
| 3.50 | 1.0 | 67.6 | 31.4 | 0.01 |
| 3.75 | 0.0 | 68.0 | 32.1 | 0 |
| 4 | 0.2 | 68.0 | 31.8 | 0 |
| 5 | 1.3 | 67.1 | 31.6 | 0.02 |
| 6 | 0.0 | 69.1 | 30.9 | 0 |
| 7 | 0.2 | 68.3 | 31.6 | 0 |
| 8 | 0.4 | 67.7 | 32.0 | 0 |
| 9 | 0.0 | 68.3 | 31.7 | 0 |
| 10 | 0.3 | 68.3 | 31.4 | 0 |
| 11 | 0.0 | 68.9 | 31.1 | 0 |
| 12 | 0.0 | 68.5 | 31.5 | 0 |
| 13 | 0.1 | 68.6 | 31.3 | 0 |
| 14 | 0.0 | 68.5 | 31.5 | 0 |
| 15 | 0.6 | 67.8 | 31.7 | 0 |
| 16 | 0.9 | 67.5 | 31.6 | 0.01 |
| 17 | 0.0 | 68.1 | 31.9 | 0 |
| 18 | 0.0 | 68.7 | 31.3 | 0 |
| 19 | 0.6 | 67.5 | 31.9 | 0 |
| 21 | 0.4 | 67.6 | 32.0 | 0 |
| 23 | 0.0 | 67.8 | 32.2 | 0 |
| 25 | 0.3 | 68.2 | 31.5 | 0 |
| 27 | 0.0 | 68.3 | 31.7 | 0 |
| 29 | 0.0 | 67.9 | 32.1 | 0 |
| 33 | 0.0 | 68.5 | 31.5 | 0 |
| 37 | 0.0 | 68.1 | 31.9 | 0 |
| 41 | 0.6 | 67.9 | 31.5 | 0 |
| 45 | 0.3 | 68.0 | 31.7 | 0 |
| 49 | 7.5 | 60.7 | 31.9 | 0.12 |
| 53 | 12.5 | 55.1 | 32.4 | 0.23 |
| 57 | 16.5 | 50.3 | 33.2 | 0.32 |
| 61 | 23.9 | 44.0 | 32.1 | 0.54 |
| 65 | 27.2 | 40.9 | 31.9 | 0.66 |
| 69 | 29.0 | 38.5 | 32.6 | 0.75 |
| 73 | 30.7 | 36.5 | 32.8 | 0.84 |
| 77 | 31.6 | 36.0 | 32.4 | 0.88 |
| 81 | 31.9 | 36.9 | 31.2 | 0.86 |
| 85 | 32.0 | 35.7 | 32.3 | 0.90 |
| 89 | 32.5 | 35.1 | 32.4 | 0.92 |

*C:O ratios less than 0.01 were presented in Table 3 as “0”.

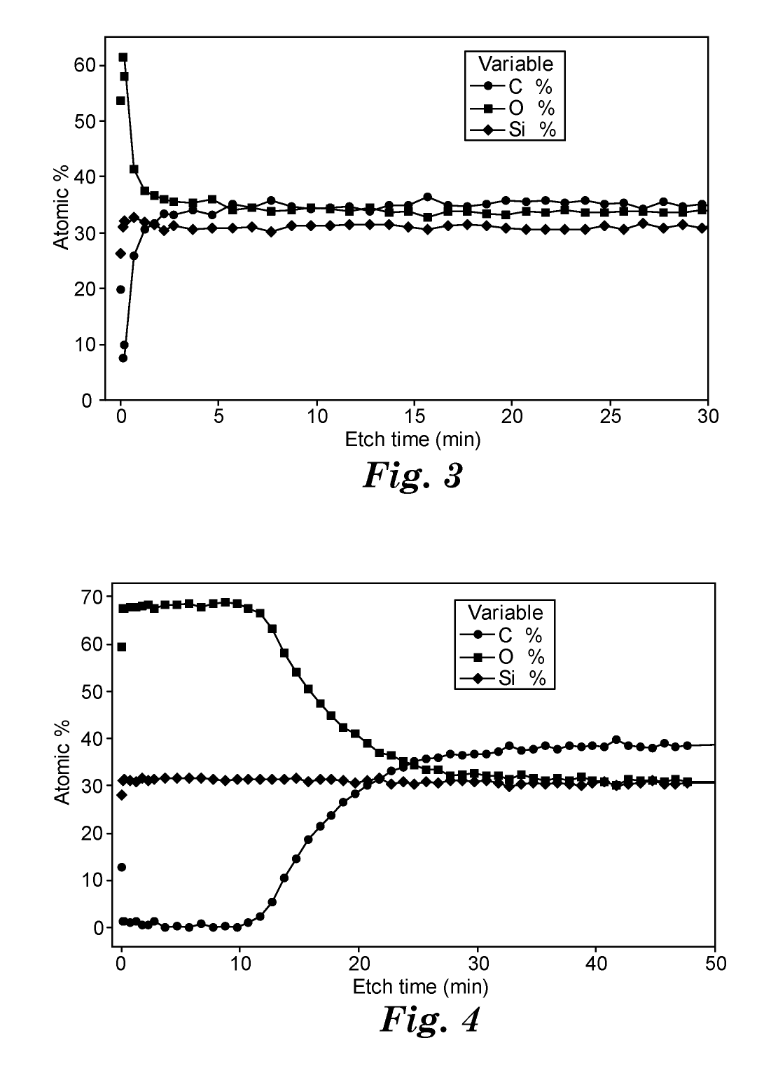

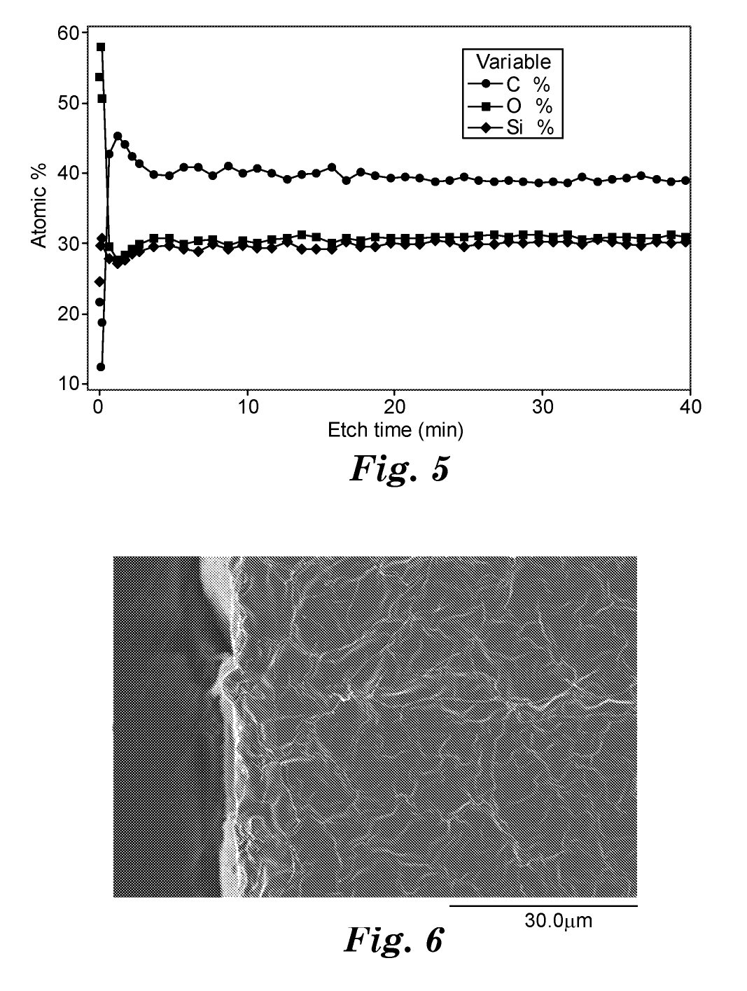

FIG. 3 shows the results from the XPS data for E1 composition after plasma treatment under the O₂ plasma conditions. FIG. 4 shows the XPS data for E2 after plasma treatment under the O₂—SiMe₄ plasma only conditions. FIG. 5 shows the XPS data for E2 under the O₂ plasma conditions.

### SEM Surface Characterization Edge Seal

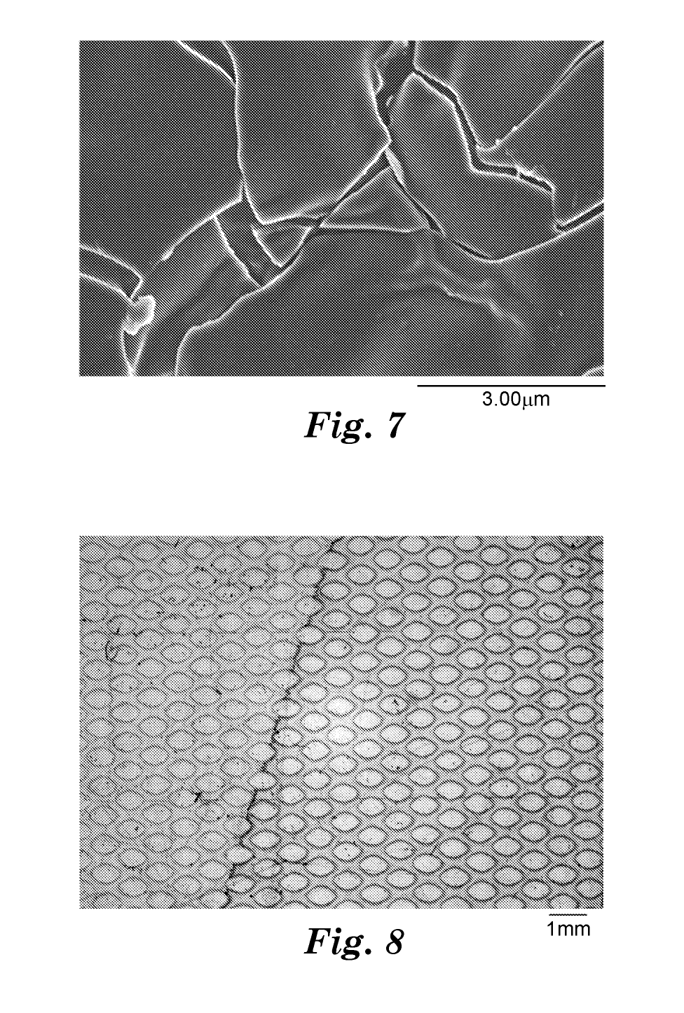

A sample of E1 (with liner L1 removed) was laminated to a glass slide. The second liner L2 was then removed and a second glass slide was laminated to the top E1 PSA surface. The exposed edge of E1 was then treated with the O₂—SiMe₄ plasma treated per above procedure. The surface of E1 after O₂—SiMe₄ plasma treatment was characterized by SEM. A plasma-generated glassy material could be seen on the surface for both samples. Two edge images at two magnifications are shown and glassy fragments are visible. FIG. 6 shows the edge at a magnification of 1500×, and FIG. 7 shows the edge at a magnification of 15,000×.

### SEM and Optical Microscope Characterization of E3 Hex and E3 Linear

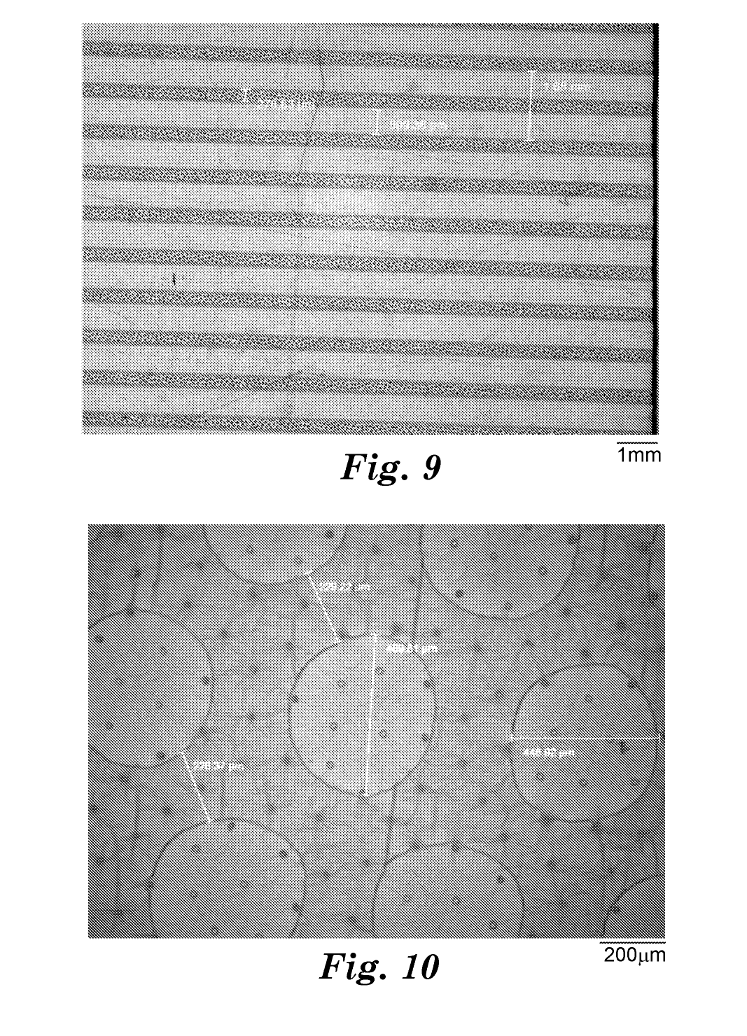

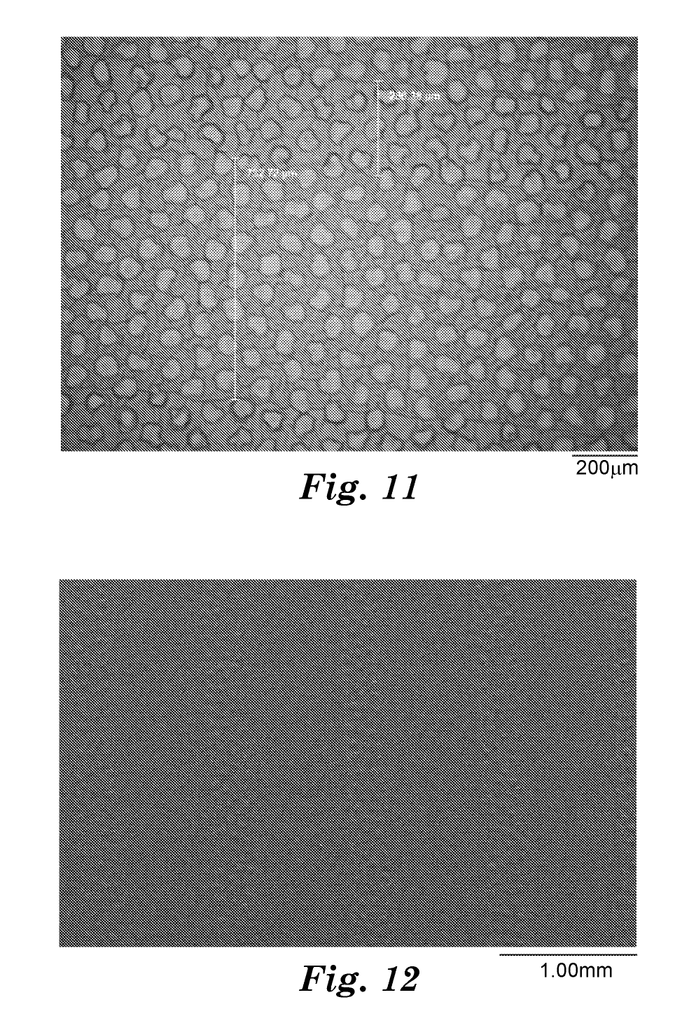

Optical microscope and SEM images of the surface of the hex structured E3 Hex silicone polyoxamide layer (after structured liner removal) can be seen in FIG. 8 and FIG. 14 and an image of the surface of the linear structured E3 Linear silicone polyoxamide layer (after structured liner removal) can be seen in FIG. 9 and FIG. 12.

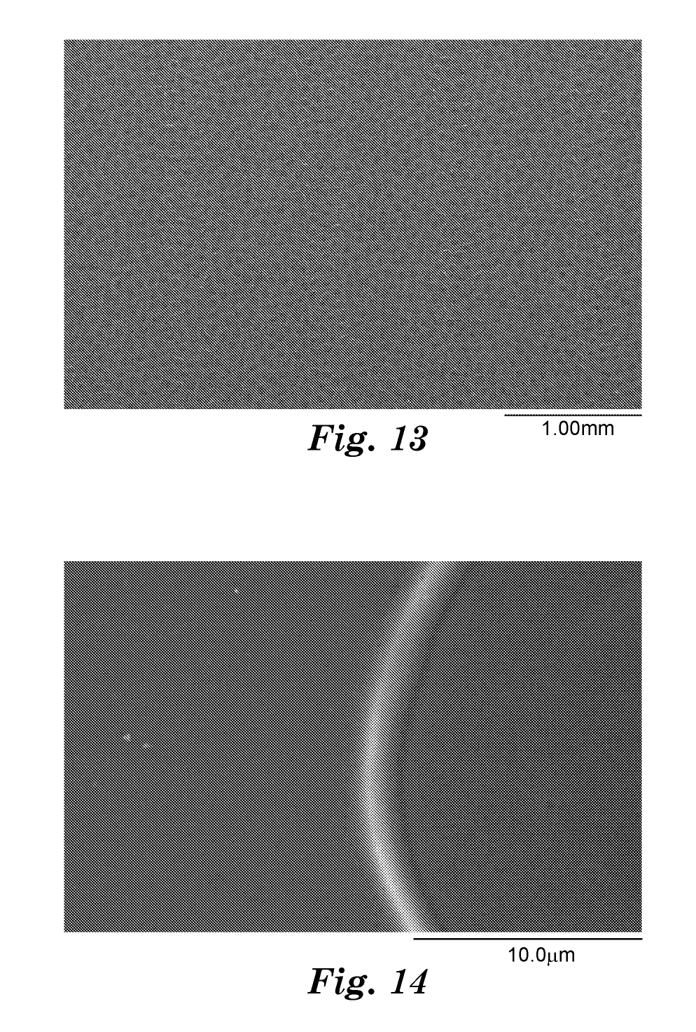

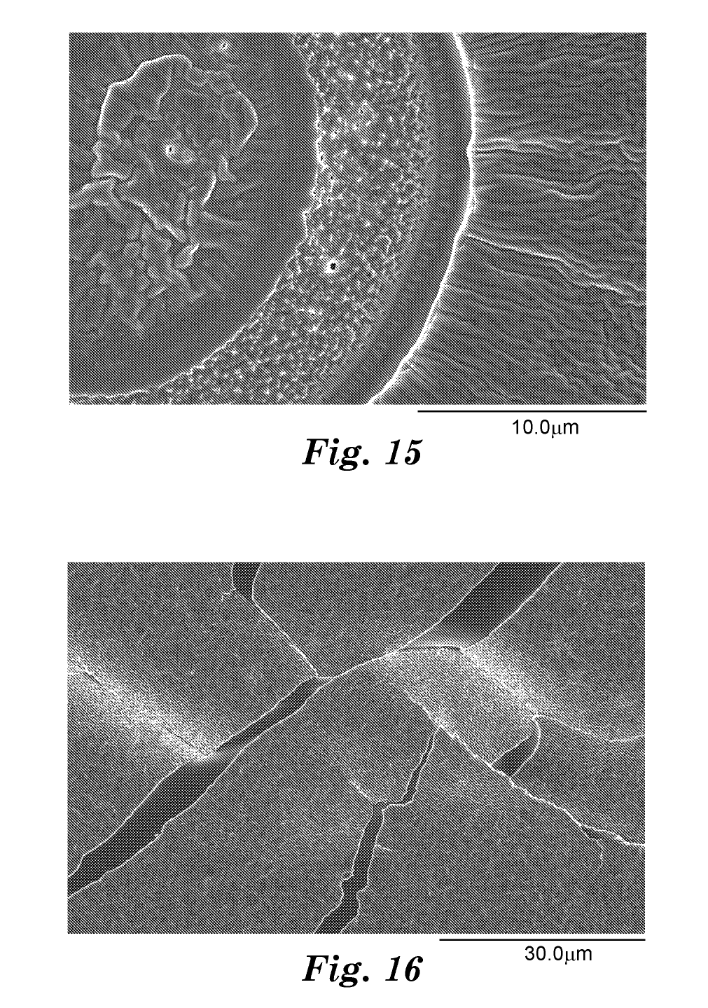

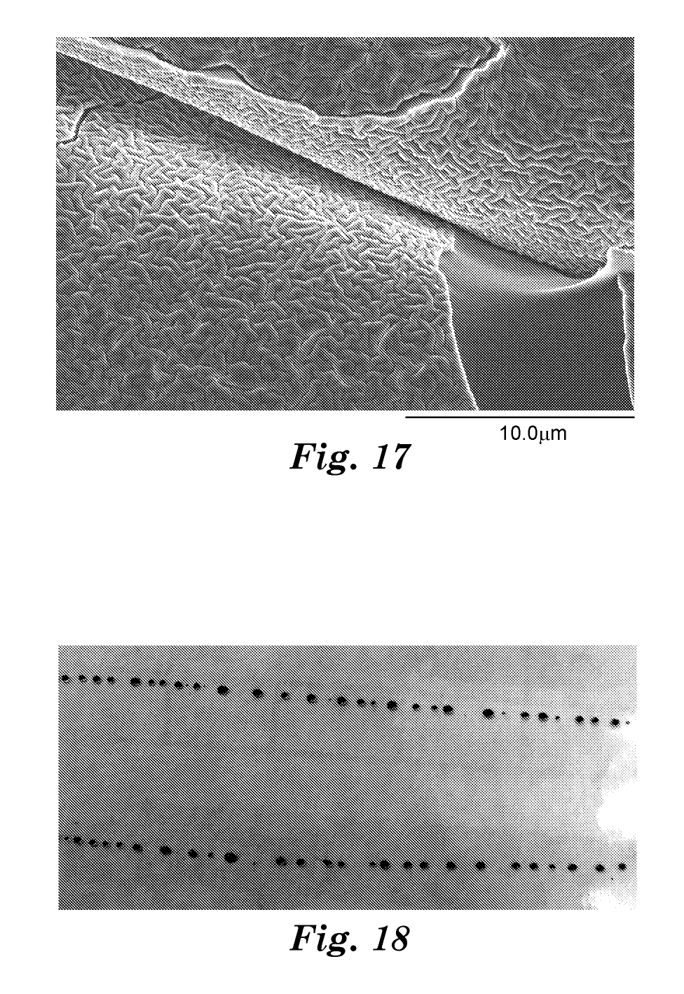

The two samples (E3 Hex and E3 Linear) were then O₂—SiMe₄ plasma treated as discussed above. Optical microscope and SEM images of the surface of the E3 Hex silicone polyoxamide layer after plasma treatment can be seen in FIG. 10 and FIG. 15 and Optical microscope and SEM images of the surface of the E3 Linear silicone polyoxamide layer after plasma treatment can be seen in FIG. 11 and FIG. 13. In FIG. 11 and FIG. 13 the printed structures that were pressed into the adhesive layer during lamination of the embossed liner are visible.

### Stretched Processing

The L1 liner was removed from a sample of Example 2 (E2). A 4″×6″ sample of FILM 1 (liner removed) was laminated to the exposed surface. L2 liner was then removed and the sample stretched in one direction doubling the samples length and held in place. The sample was O₂—SiMe₄ plasma treated as described above. Once treatment was complete the sample was relaxed to original dimension. SEM images were taken and can be seen in FIG. 16 (1500× magnification) and 17 (5000× magnification).

### Ink Receptivity Test

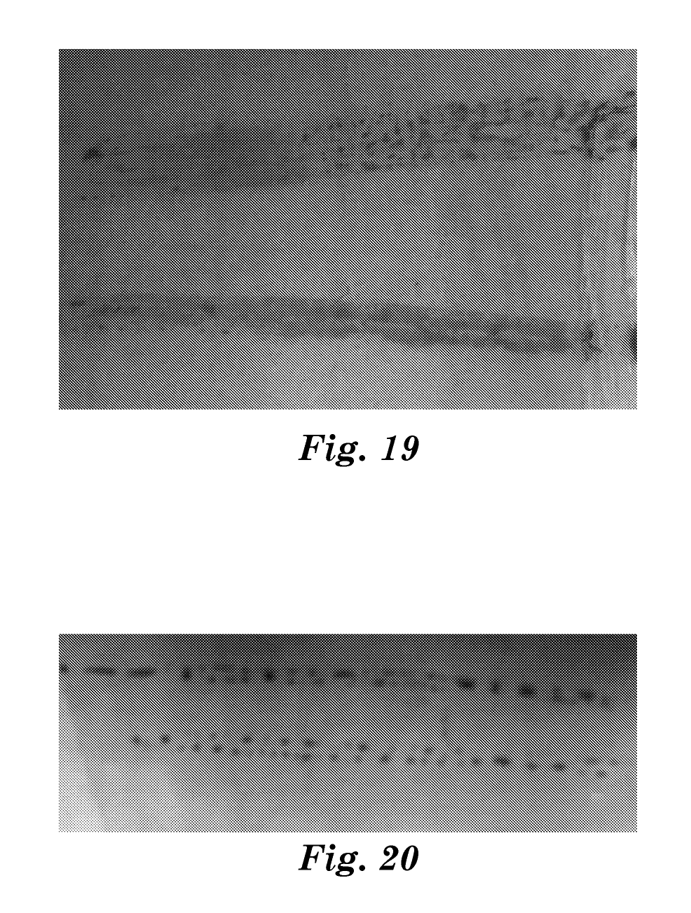

Samples E1 and C2 before and 11 days after O₂ plasma treatments were drawn on with MARKER. Two (2) parallel lines were drawn with MARKER on both samples and images were captured. FIG. 18 shows the image of E1 before treatment, FIG. 19 shows E1 11 days after plasma treatment, and FIG. 20 shows C2 11 days after plasma treatment. Results are shown in Table 4. No corresponds to no wetting. Yes corresponds to wetting

TABLE 4

| Example | Wetting of surface by ink |
|---|---|
| E1 (no treatment) | No |
| E1 (11 days after O₂ treatment) | Yes |
| C2 (no treatment) | NA |
| C2 (11 days after O₂ treatment) | No |

Thus, embodiments of COMPOSITE STRUCTURE INCLUDING GLASS-LIKE LAYER AND METHODS OF FORMING are disclosed. The disclosed embodiments are presented for purposes of illustration and not limitation. One will also understand that components depicted and described with regard to the figures and embodiments herein may be interchangeable.

1. A composite structure comprising:
a first layer comprising a silicone block copolymer;
a transition layer, the transition layer having a first surface contiguous with the first layer and a second opposing surface, the transition layer formed from the silicone block copolymer of the first layer;
a glass-like layer contiguous with the second surface of the transition layer, at least a portion of the glass-like layer formed from the transition layer.

2. The composite structure according to claim 1, wherein the silicone block copolymer is a condensation silicone block copolymer.

3. The composite structure according to claim 1, wherein the silicone block copolymer comprises silicone polyoxamide copolymers, silicone polyurea copolymers, or combinations thereof.

4. The composite structure according to claim 1, wherein the silicone block copolymer is an adhesive.

5. The composite structure according to claim 1, wherein the silicone block copolymer is a pressure sensitive adhesive.

6. The composite structure according to claim 1, wherein the silicone block copolymer comprises silicone polyoxamide copolymers, silicone polyurea copolymers, or combinations thereof; and tackifying resin.

7. The composite structure according to claim 6, wherein the tackifying resin comprises MQ tackifying resins.

8. The composite structure according to claim 1, wherein the first layer comprises: 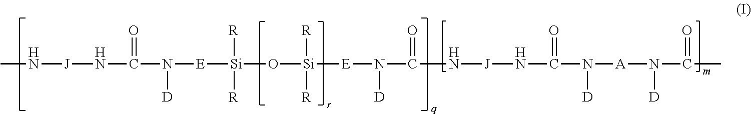
wherein
each R is a moiety that, independently, is an alkyl moiety, having 1 to 12 carbon atoms, and may be substituted with, for example, trifluoroalkyl or vinyl groups, a vinyl radical or higher alkenyl radical represented by the formula R²(CH₂)ₐCH═CH₂ wherein R² is —(CH₂)_{b}— or —(CH₂)_{c}CH═CH— and a is 1, 2 or 3; b is 0, 3 or 6; and c is 3, 4 or 5, a cycloalkyl moiety having from 6 to 12 carbon atoms and may be substituted with alkyl, fluoroalkyl, or vinyl groups, or an aryl moiety having from 6 to 20 carbon atoms and may be substituted with, for example, alkyl, cycloalkyl, fluoroalkyl and vinyl groups or R is a perfluoroalkyl group, or a fluorine-containing group, or a perfluoroether-containing group;
each J is a polyvalent radical that is an arylene radical or an aralkylene radical having from 6 to 20 carbon atoms, an alkylene or cycloalkylene radical having from 6 to 20 carbon atoms;
each E is a polyvalent radical that independently is an alkylene radical of 1 to 10 carbon atoms, an aralkylene radical or an arylene radical having 6 to 20 carbon atoms;
each D is selected from the group consisting of hydrogen, an alkyl radical of 1 to 10 carbon atoms, phenyl, and a radical that completes a ring structure including A or E to form a heterocycle;
each A is a polyvalent radical selected from the group consisting of alkylene, aralkylene, cycloalkylene, phenylene, heteroalkylene, and mixtures thereof;
m is a number that is 0 to 1000;
q is a number that is at least 1; and
r is a number that is at least 10.

9. The composite structure according to claim 1, wherein the first layer comprises: 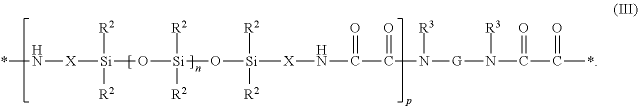
wherein
each R² is independently an alkyl, haloalkyl, aralkyl, alkenyl, aryl, or aryl substituted with an alkyl, alkoxy, or halo, wherein at least 50 percent of the R² groups are methyl;
each X is independently an alkylene, aralkylene, or a combination thereof;
G is a divalent group that is the residue unit that is equal to a diamine of formula R³HN-G-NHR³ minus the two —NHR³ groups,
where R³ is hydrogen or alkyl or R³ taken together with G and the nitrogen to which they are both attached forms a heterocyclic group;
n is independently an integer of 40 to 1500;
the subscript p is an integer of 1 to 10.

10. The composite structure according to claim 1, wherein the first layer has an oxygen normalized carbon to oxygen ratio, the transition layer has an oxygen normalized carbon to oxygen ratio and the glass-like layer has an oxygen normalized carbon to oxygen ratio, and the oxygen normalized carbon to oxygen ratio of the first layer is higher than both the transition layer and the glass-like layer.

11. The composite structure according to claim 10, wherein the oxygen normalized carbon to oxygen ratio of the transition layer is higher than that of the glass-like layer.

12. The composite structure according to claim 10, wherein the oxygen normalized carbon to oxygen ratio of the transition layer decreases from the first layer to the second layer.

13. The composite structure according to claim 1, wherein the first layer is more elastic than both the transition layer and the glass-like layer.

14. The composite structure according to claim 13, wherein the transition layer is more elastic than the glass-like layer.

15. The composite structure according to claim 1, wherein the glass-like layer is harder than both the transition layer and the first layer.

16. The composite structure according to claim 15, wherein the transition layer is harder than the first layer.

17. The composite structure according to claim 1, wherein the transition layer and the glass-like layer were formed by plasma treating material of the first layer.

18. The composite structure according to claim 1, wherein the transition layer has a thickness from 1 nm to 200 nm.

19. The composite structure according to claim 18, wherein the thickness of the transition layer, the thickness of the glass-like layer, or both are at least somewhat controlled by the total time of plasma treatment.

20-52. (canceled)

53. An article comprising:
a primary structure; and
a composite structure, the composite structure disposed on at least some surface of the primary structure, the composite structure comprising:
a first layer comprising a silicone block copolymer;
a transition layer, the transition layer having a first surface contiguous with the first layer and a second opposing surface, the transition layer formed from the silicone block copolymer of the first layer;
a glass-like layer contiguous with the second surface of the transition layer, at least a portion of the glass-like layer formed from the transition layer.

54-56. (canceled)
